(19) United States
(12) Patent Application Publication
(10) Pub. No.: US 2024/0191131 A1
(43) Pub. Date: Jun. 13, 2024

(54) METHOD FOR MANUFACTURING LIGHT-EMISSION TYPE ORGANIC NANOPARTICLES, LIGHT-EMISSION TYPE ORGANIC NANOPARTICLES MANUFACTURED THEREBY, COMPOSITION FOR COLOR CONVERSION FILM, COLOR CONVERSION FILM, DISPLAY DEVICE, AND LIGHT-EMITTING DIODE DEVICE

(71) Applicant: ND-Materials Corp., Seoul (KR)

(72) Inventors: Jang Hyuk KWON, Seongnam-si (KR); Bright James WALKER, Seoul (KR); Soon Jae HWANG, Seoul (KR); Young Hun JUNG, Seoul (KR)

(73) Assignee: ND-Materials Corp., Seoul (KR)

(21) Appl. No.: 18/280,488

(22) PCT Filed: Apr. 28, 2022
(86) PCT No.: PCT/KR2022/006088

§ 371 Date: Sep. 6, 2023

(30) Foreign Application Priority Data
Jun. 30, 2021 (KR) 10-2021-0086160

(51) Int. Cl. C09K 11/06; C09K 11/02; H01L 33/50

(52) U.S. Cl. CPC C09K 11/06; C09K 11/02; C09K 2211/1018; H01L 33/502

(57) ABSTRACT

Provided is a method for manufacturing small and uniform light-emission type organic nanoparticles with improved yield. The method for manufacturing light-emission type organic nanoparticles according to the present invention comprises the steps of: (S1) preparing the first mixture by mixing an organic phosphor and a surfactant; and (S2) preparing a dispersion solution by mixing the first mixture with the first solvent which is an anti-solvent for the organic phosphor.

### TECHNICAL FIELD

The present invention relates to a method of preparing light-emission type organic nanoparticles, light-emission type organic nanoparticles prepared thereby, a composition for a color conversion film, a method of manufacturing a color conversion film using the same, a color conversion film, a display device, and a light emitting diode device, and more specifically, a method of preparing light-emission type organic nanoparticles, which provides excellent photochemical stability and does not use heavy metals to prevent environmental pollution, light-emission type organic nanoparticles prepared thereby, a composition for a color conversion film, a method of manufacturing a color conversion film using the same, a color conversion film, a display device, and a light emitting diode device.

### BACKGROUND ART

In order to generate white light from a light emitting diode, a method of using a blue light emitting diode and a phosphor, organic dye, quantum dot, or the like as a color conversion film is mainly used. At this time, a material of a color conversion film should have a wide full width at half maximum (FWHM) to have a high color rendering index and should have good heat resistance to withstand the heat of the light emitting diode. On the other hand, since the material of the color conversion film used in a display should have light emitting characteristics with a small full width at half maximum in order to have good color purity, unlike a light emitting diode, fluorescence, phosphorescence, quantum dots, or the like are mainly used.

A method using a blue LED and a yellow phosphor, which are most widely used in the light emitting diode, has a disadvantage in that it has a high correlated color temperature because the color rendering index is low and the yellow phosphor emits little red light. When the organic dye is used in a color conversion layer, they have an aggregation property during light emission, resulting in quenching and low photochemical stability.

Quantum Dots (QDs) using inorganic materials have the advantage of good light conversion efficiency (photoluminescence quantum yield, PLQY), a fast response time, and high reliability. However, there are disadvantages in that it is difficult to use it as a color conversion film for a light emitting diode since the quantum dot is very vulnerable to moisture and has poor heat resistance, and using heavy metals such as cadmium, arsenic, and lead. Specifically, heavy metals such as lead, cadmium, mercury, chromium, arsenic, and the like are emerging as a major public health problem due to their high accumulation properties in the body. Heavy metals absorbed into the body are accumulated in the hair and organ tissue through blood, and the residence time of heavy metals in the body is relatively short in blood or urine, but in the case of hair, it lasts for a relatively long time. In general, the accumulation of heavy metals in the body occurs through a continuous food chain and shows bioaccumulative properties, in which the concentration in the body of predators increases compared to prey. In particular, cadmium, which is used as a fluorescent material, can cause serious damage to the stomach, lungs, and bones.

In general, a method of producing organic nanoparticles is typically classified into an emulsification method, a nano-precipitation method, and a reprecipitation method.

In particular, a method using a surfactant has advantages over other methods in terms of uniformity and yield of nanoparticles. In the general reprecipitation method, when an anti-solvent is added to a solution, since particles with various sizes and shapes are created, the uniformity of the nanoparticles is deteriorated, and when nanoparticles of a certain size are obtained through centrifugation to increase uniformity, there is a problem in that the synthesis yield is lowered.

### DISCLOSURE

### Technical Problem

The present invention is directed to providing a method of preparing light-emission type organic nanoparticles with high yield by preparing small and uniform light-emission type organic nanoparticles in order to solve the above problems.

The present invention is also directed to providing a method of preparing light-emission type organic nanoparticles that can replace quantum dots using heavy metals that cause environmental pollution and have bioaccumulative properties.

The present invention is also directed to providing light-emission type organic nanoparticles prepared by the method of preparing the light-emission type organic nanoparticles.

The present invention is also directed to providing a composition for a color conversion film, including the light-emission type organic nanoparticles.

The present invention is also directed to providing a method of manufacturing a color conversion film using the composition for the color conversion film.

The present invention is also directed to providing a color conversion film manufactured by the method of manufacturing the color conversion film having excellent photochemical stability, high color conversion efficiency, and long-lasting performance.

The present invention is also directed to providing a display device including the color conversion film.

The present invention is also directed to providing a light emitting diode device including the color conversion film.

The objects of the present invention are not limited to the above-mentioned objects, and other objects and advantages of the present invention not mentioned above can be understood by the following description and will be more clearly understood by the examples of the present invention. It will also be readily apparent that the objects and advantages of the present invention may be realized by the means and combinations thereof set forth in the claims.

### Technical Solution

One embodiment of the present invention for achieving the above objects is a method of preparing light-emission type organic nanoparticles, including: (S1) preparing a first mixture by mixing an organic phosphor and a surfactant; and (S2) preparing a dispersion solution by mixing the first mixture with a first solvent which is an anti-solvent for the organic phosphor.

Another embodiment of the present invention for achieving the above objects is light-emission type organic nanoparticles prepared by the method of preparing light-emission type organic nanoparticles.

Still another embodiment of the present invention for achieving the above objects is a composition for a color conversion film including: a polymer resin; and 2 to 20 parts by weight of the light-emission type organic nanoparticles, based on 100 parts by weight of the polymer resin.

Yet another embodiment of the present invention for achieving the above objects is a method of manufacturing a color conversion film, including applying the composition for a color conversion film on a substrate.

Yet another embodiment of the present invention for achieving the above objects is a color conversion film coated with the composition for a color conversion film on a substrate.

Yet another embodiment of the present invention for achieving the above objects is a display device including the color conversion film.

Yet another embodiment of the present invention for achieving the above objects is a light emitting diode device including the color conversion film.

### Advantageous Effects

According to one embodiment of the present invention, small and uniform light-emission type organic nanoparticles can be prepared in high yield, and environmental pollution problems can be prevented because quantum dots are not used. In addition, according to one embodiment of the present invention, a color conversion film having excellent photochemical stability, high color conversion efficiency, and long-lasting performance can be provided by using the light-emission type organic nanoparticles.

In addition to the above-described effects, the specific effects of the present invention will be described together while describing specific details for carrying out the invention below.

### DESCRIPTION OF DRAWINGS

FIG. 1 shows a schematic diagram showing a method of preparing light-emission type organic nanoparticles (Ttrz-DI NPs) according to an embodiment of the present invention.

FIG. 2 shows the ¹H NMR data of the novel Ttrz-DI.

FIG. 3A shows the UV-Vis, room temperature photoluminescence (RTPL), and low temperature photoluminescence (LTPL) spectra of Ttrz-DI in toluene.

FIG. 3B shows the time resolved photoluminescence (TRPL) of Ttrz-DI.

FIG. 4 shows optical micrographs of organic nanoparticles in the absence of TritonX-100 (Comparative Example 1) and in the case of varying the concentration of TritonX-100 from 0.2 mM to 10.0 mM, when the organic nanoparticles are prepared by a method of preparing light-emission type organic nanoparticles according to Example 1-1.

FIG. 5 shows optical micrographs of organic nanoparticles in the absence of TBAOleate (Comparative Example 1) and in the case of varying the concentration of TBAOleate from 0.2 mM to 10.0 mM, when the organic nanoparticles are prepared by a method of preparing light-emission type organic nanoparticles according to Example 1-2.

FIG. 6 shows optical micrographs of organic nanoparticles in the absence of TritonX-100 (Comparative Example 1) and in the case of varying the concentration of TritonX-100 from 0.2 mM to 10.0 mM, when the organic nanoparticles are prepared by a method of preparing light-emission type organic nanoparticles according to Example 2-1.

FIG. 7 shows optical micrographs of organic nanoparticles in the absence of TritonX-100 (Comparative Example 1) and in the case of varying the concentration of TritonX-100 from 0.2 mM to 10.0 mM, when red organic nanoparticles are prepared by a method of preparing light-emission type organic nanoparticles according to Example 3-1.

FIG. 8A shows the case when a surfactant is Triton X-100, when Ttrz-DI is in solution, is a film, and is dispersed in a dispersion solution in the order from left to right.

FIG. 8B shows the case when a surfactant is TBAOleate, when Ttrz-DI is in solution, is a film, and is dispersed in a dispersion solution in the order from left to right.

FIG. 9 shows a luminescence intensity of the light-emission type organic nanoparticles in the absence of a surfactant and in the case where the concentration of the surfactant was varied from 0.2 mM to 10 mM, on the premise that 0.01 mM of Ttrz-DI was added, when light-emission type organic nanoparticles are prepared by a preparation method according to Example 1-1.

FIG. 10A shows a luminescence intensity of the light-emission type organic nanoparticles in the absence of a surfactant and in the case where the concentration of the surfactant was varied from 0.2 mM to 10 mM, on the premise that 0.01 mM of CzDABNA was added, when light-emission type organic nanoparticles are prepared by a preparation method according to Example 2-1.

FIG. 10B shows a luminescence intensity of the light-emission type organic nanoparticles in the absence of a surfactant and in the case where the concentration of the surfactant (Triton X-100) was varied from 0.2 mM to 10 mM, on the premise that 0.01 mM of 4tBuMB was added, when light-emission type organic nanoparticles are prepared by a preparation method according to Example 3-1.

FIG. 11A shows the yield of organic nanoparticles having an average size of less than 200 nm (nanometers) according to the concentration of a surfactant.

FIG. 11B shows the yield of organic nanoparticles having an average size of less than 450 nm according to the concentration of a surfactant.

FIG. 12A shows the optical properties of the color conversion film according to Example 4.

FIG. 12B shows a method for measuring the color conversion efficiency of a color conversion film according to Example 4.

FIG. 13A shows the optical properties of the color conversion film according to Example 5.

FIG. 13B shows a method for measuring the color conversion efficiency of a color conversion film according to Example 5.

FIG. 14A shows the optical properties of the color conversion film according to Example 6.

FIG. 14B shows a method for measuring the color conversion efficiency of a color conversion film according to Example 6.

FIG. 15 shows the color conversion efficiency of color conversion films according to Examples 4 to 7 and Comparative Example 2.

FIG. 16A shows a luminescence intensity obtained by measuring a luminescence spectrum at room temperature over time when color conversion films according to Examples 4 to 7 and Comparative Example 2 were continuously exposed to UV (wavelength: 365 nm) for 120 hours.

FIG. 16B shows a change amount (%) in color conversion efficiency of each of the newly prepared color conversion films according to Examples 4 to 7 and Comparative Example 2 after being allowed to stand for one month.

### MODES OF THE INVENTION

Hereinafter, each configuration of the present invention will be described in more detail so that those skilled in the art can easily practice it, but this is only one example, and the scope of the present invention is not limited.

A method of preparing light-emission type organic nanoparticles according to an aspect of the present invention includes: (S1) preparing a first mixture by mixing an organic phosphor and a surfactant; and (S2) preparing a dispersion solution by mixing the first mixture with a first solvent which is an anti-solvent for the organic phosphor. According to one embodiment of the present invention, by mixing the surfactant with the organic phosphor, it is possible to provide smaller and more uniform light-emission type organic nanoparticles than a method of preparing light-emission type organic nanoparticles through a reprecipitation method using an anti-solvent.

Hereinafter, the configuration of the present invention will be described in more detail with reference to the drawings.

### 1. Method of Preparing Light-Emission Type Organic Nanoparticles and Light-Emission Type Organic Nanoparticles Prepared Thereby

After passing through the steps (S1) and (S2), the method of preparing light-emission type organic nanoparticles according to the present invention may further include dialyzing the dispersion solution and drying the dialyzed dispersion solution. For example, the method of preparing light-emission type organic nanoparticles according to the present invention may include filtering the dispersion solution through a filter, and then putting an obtained product into a dialyzer and concentrating the product under vacuum for 10 to 12 hours. By dialyzing the dispersion solution through the dialyzer, excess surfactant can be removed from the dispersion solution, and the concentration of the light-emission type organic nanoparticles can be adjusted. The dialyzer may correspond to, for example, a dialysis tube made of cellulose acetate.

The organic phosphor according to the present invention may correspond to any one selected from the group consisting of a green phosphor, a blue phosphor, and a red phosphor. As the green phosphor, various green phosphors may be used in the technical field to which the present invention belongs, and likewise, various organic phosphors may be used as the blue phosphor and the red phosphor.

According to one embodiment of the present invention, the organic phosphor is a delayed fluorescence material, and a luminescence efficiency may correspond to 80% or more. The delayed fluorescence material according to the present invention refers to a thermally activated delayed fluorescence material (TADF) and corresponds to a material capable of increasing internal quantum efficiency. Specifically, the thermally activated delayed fluorescence material corresponds to a material that emits fluorescence by moving three triplet excitons, which are particles that are extinguished by heat or vibration, to the level of a singlet exciton using heat.

The delayed fluorescence material may correspond to a compound represented by Chemical Formula 1 below.

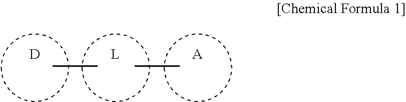

in Chemical Formula 1, L is any one selected from the group consisting of an aryl group, an arylene group, and a carbon-nitrogen single bond, and when L is an aryl group, A is a cyano group mono- or di-substituted on the aryl group, and D is a substituent tetra- or penta-substituted on the aryl group, wherein each of the substituents is independently a heteroaryl group containing a nitrogen atom substituted with a hydrocarbon group having 1 to 10 carbon atoms, and when L is an arylene group, A is a substituted or unsubstituted triazine group, D is a substituted or unsubstituted heteroaryl group, includes a conjugated or non-conjugated 5-membered or 6-membered ring containing a nitrogen atom bonded to the arylene group, is a multi-fused ring conjugated with the conjugated or non-conjugated 5-membered or 6-membered ring, and includes 1 to 9 nitrogen atoms or one Group 16 element in the multi-fused ring, and when L is a carbon-nitrogen single bond, D is a fused ring having 10 to 40 carbon atoms, includes a conjugated or non-conjugated 5-membered or 6-membered ring containing a nitrogen atom of L, includes a substituted or unsubstituted aryl group forming a fused ring with the conjugated or non-conjugated 5-membered or 6-membered ring, wherein the conjugated or non-conjugated 5-membered or 6-membered ring is a substituted or unsubstituted ring, does not include or includes a Group 16 element in the ring, and includes 1 or 2 nitrogen atoms in the ring, A is a heterocyclic ring having 15 to 40 carbon atoms, includes an aryl group containing a carbon atom bonded to L, includes a ring structure containing a boron atom and an oxygen atom in the ring, forming a fused ring with the aryl group containing the carbon atom, or includes a conjugated 5-membered or 6-membered ring structure containing two nitrogen atoms.

The present invention may be characterized in that the delayed fluorescence material is any one of compounds represented by the following Chemical Formulas T-1 to T-32.

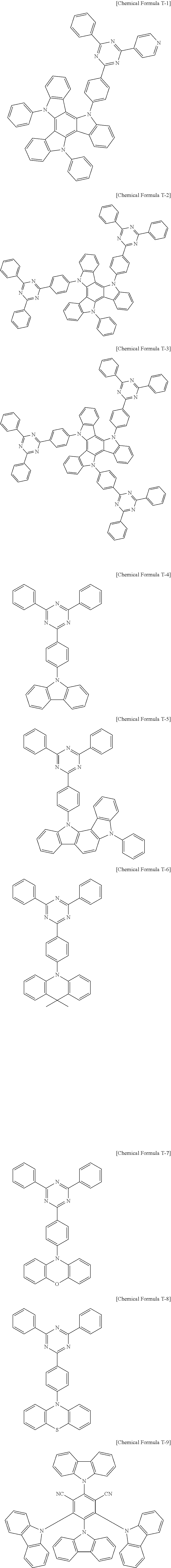

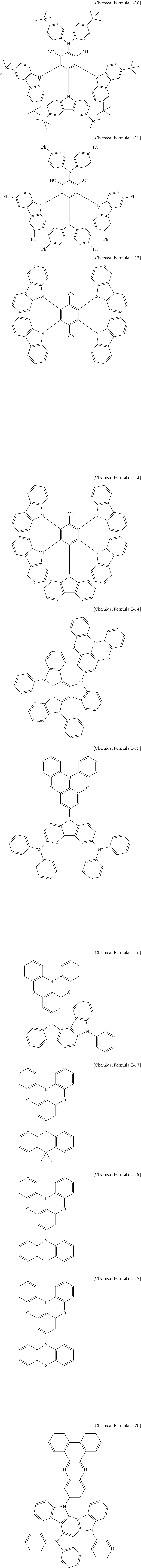

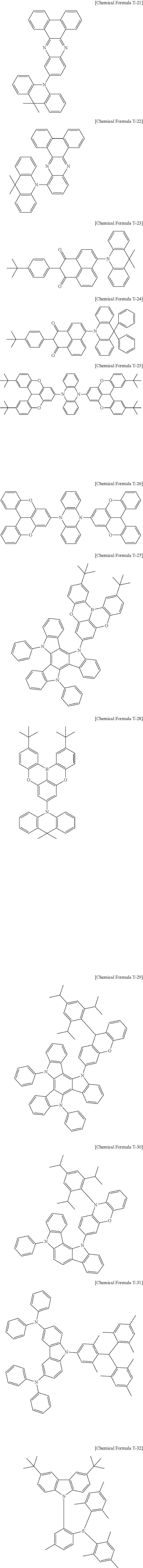

According to another embodiment of the present invention, the organic phosphor may be a phosphor having a luminescence efficiency of 80% or more and having a boron compound as a main structure.

The phosphor having a boron compound as a main structure may be a compound represented by Chemical Formula 2 below.

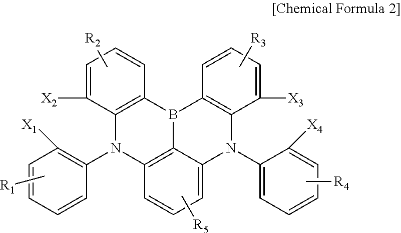

in Chemical Formula 2, R₁ to R₅ each independently correspond to any one selected from the group consisting of hydrogen, deuterium, a halogen group, a hydroxyl group, a cyano group, a nitro group, an amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, and X₁ to X₄ are each independently hydrogen, or are bonded to each other to form a ring.

The present invention may be characterized in that the boron compound is any one of compounds represented by the following Chemical Formulas D-1 to D-30.

[chemical structure]

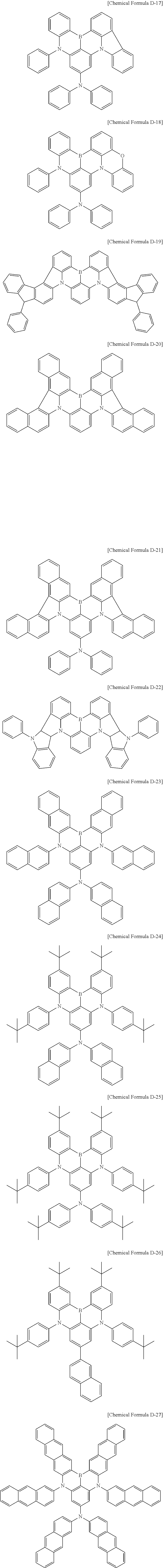

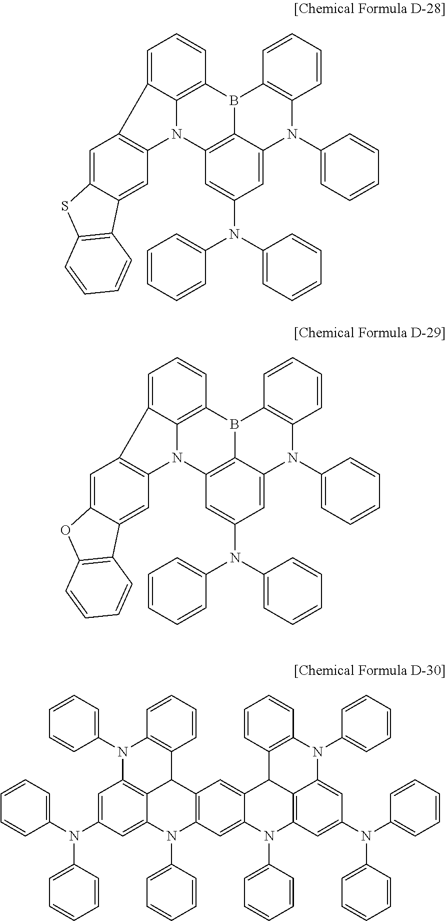 [SMILES: c1ccc(N(c2ccccc2)c2cc3c4c(c2)-n2c5cc6c(cc5c5cccc(c52)B4c2ccccc2N3c2ccccc2)sc2ccccc26)cc1 ; c1ccc(N(c2ccccc2)c2cc3c4c(c2)-n2c5cc6c(cc5c5cccc(c52)B4c2ccccc2N3c2ccccc2)oc2ccccc26)cc1 ; c1ccc(N(c2ccccc2)c2cc3c4c(c2)N(c2ccccc2)c2cc5c(cc2C4c2ccccc2N3c2ccccc2)C2c3ccccc3N(c3ccccc3)c3cc(N(c4ccccc4)c4ccccc4)cc(c32)N5c2ccccc2)cc1]

According to another embodiment of the present invention, the phosphor having a boron compound as a main structure may be a compound represented by Chemical Formula 3 below.

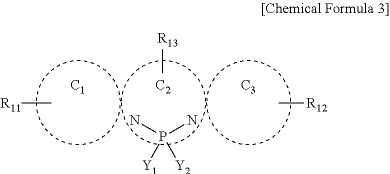

in Chemical Formula 3, C₁ to C₃ each have a 5-membered or 6-membered ring structure, and R₁₁ and R₁₂ may each be independently substituted with 1, 2 or 3 substituents, and each of the substituents independently corresponds to any one selected from the group consisting of hydrogen, deuterium, a halogen group, a hydroxyl group, a cyano group, a nitro group, an amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted thioether group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, or two or more substituents are bonded to each other to form a ring, R₁₃ corresponds to any one selected from the group consisting of hydrogen, deuterium, a halogen group, a hydroxyl group, a cyano group, a nitro group, an amino group, an amidino group, a hydrazino group, a hydrazono group, a substituted or unsubstituted alkyl group, a substituted or unsubstituted an alkenyl group, a substituted or unsubstituted alkynyl group, a substituted or unsubstituted alkoxy group, a substituted or unsubstituted thioether group, a substituted or unsubstituted cycloalkyl group, a substituted or unsubstituted cycloalkenyl group, a substituted or unsubstituted a heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, and Y₁ and Y₂ are each independently a fluorine group or an alkoxy group.

The present invention may be characterized in that the boron compound is any one of compounds represented by the following Chemical Formulas B-1 to B-32

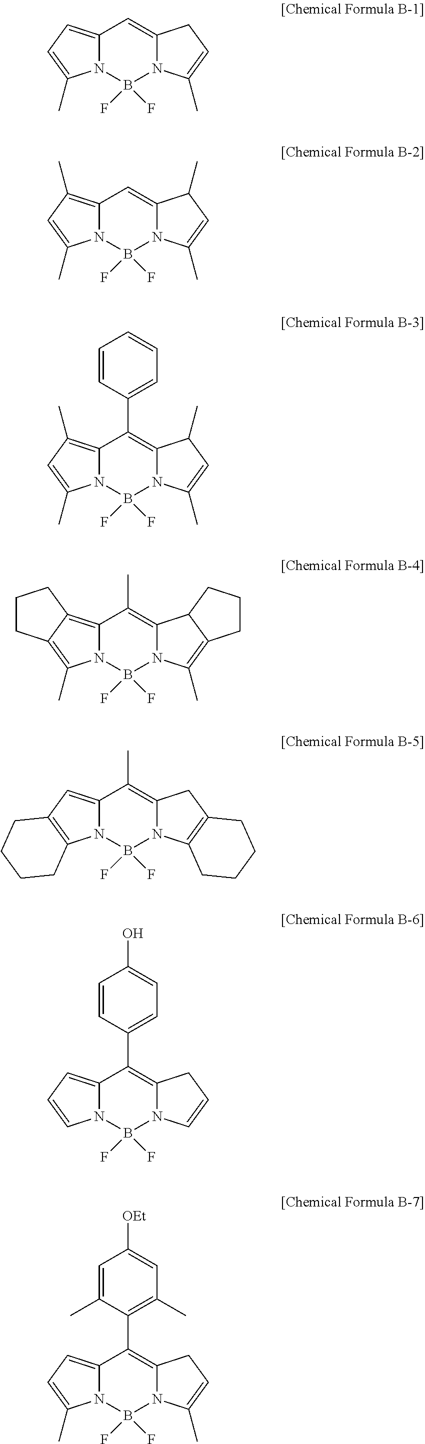

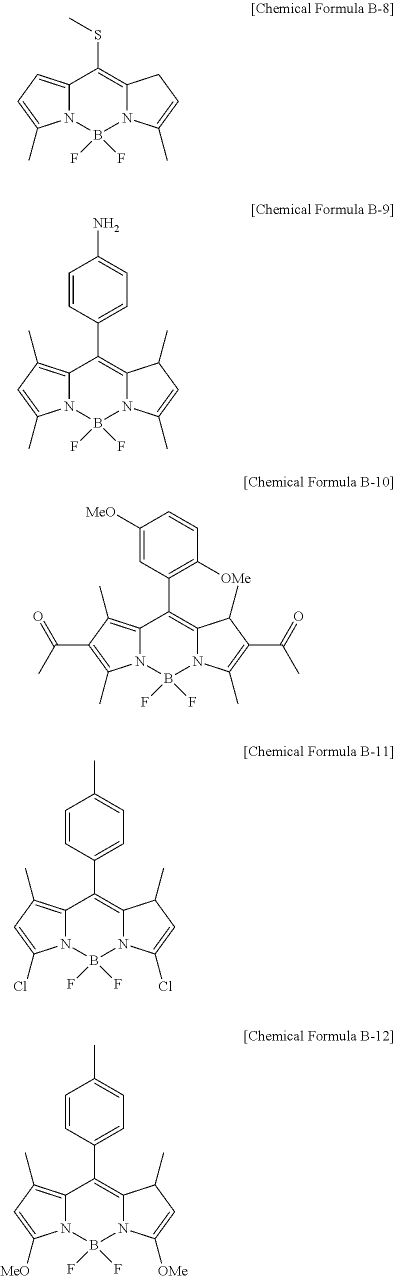

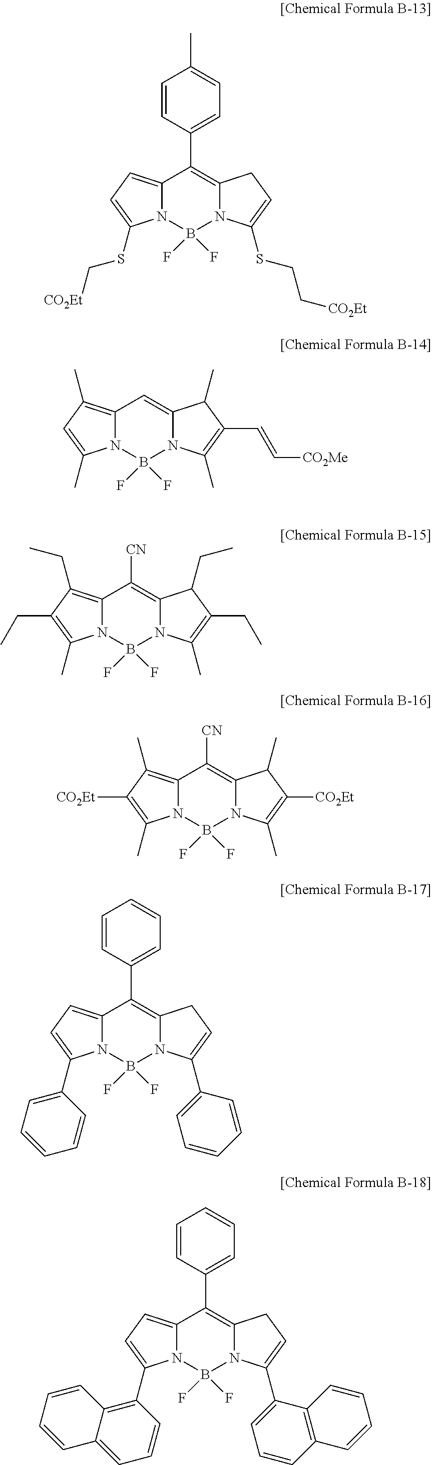

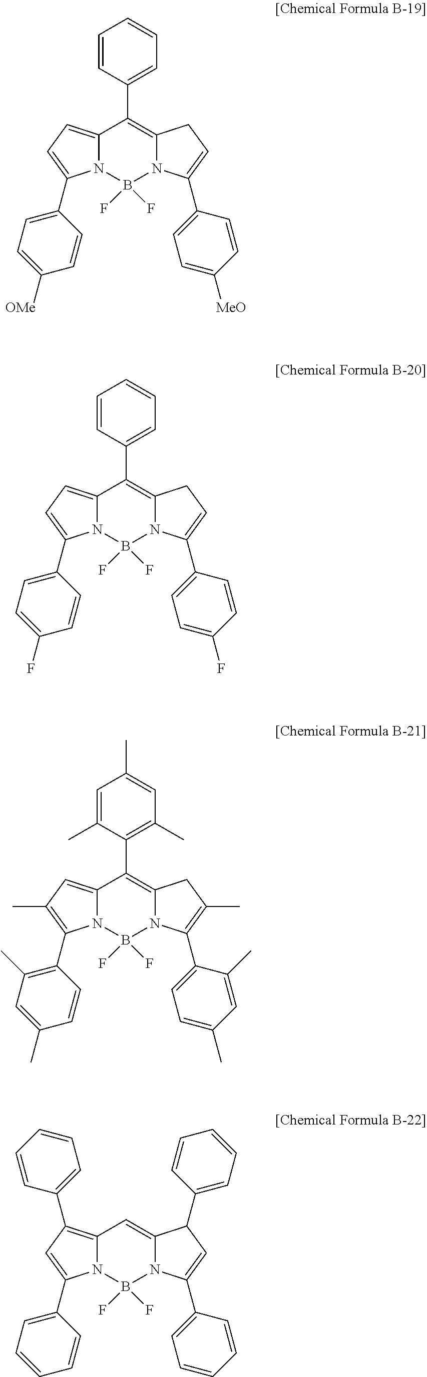

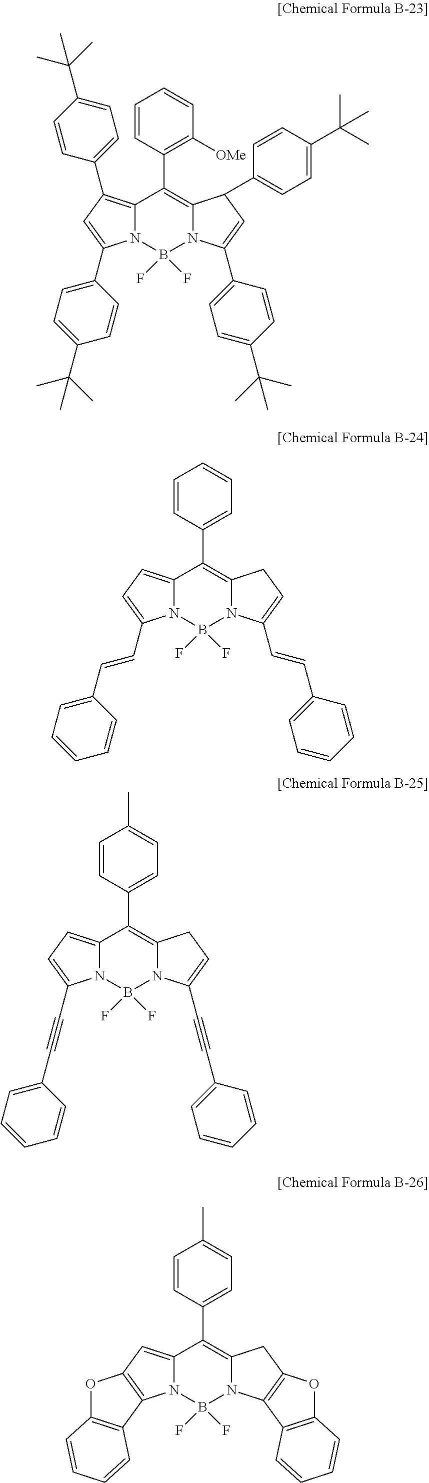

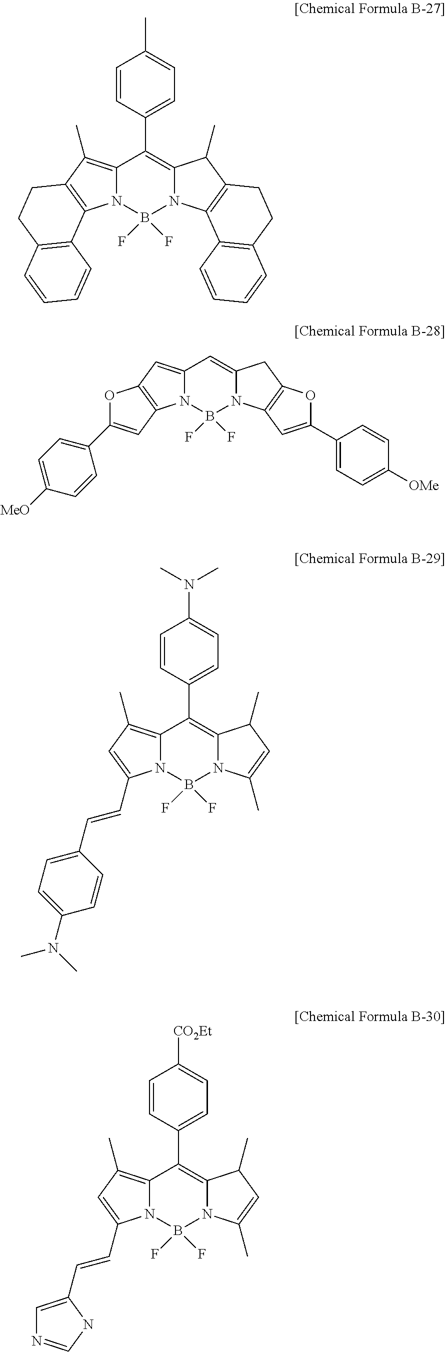

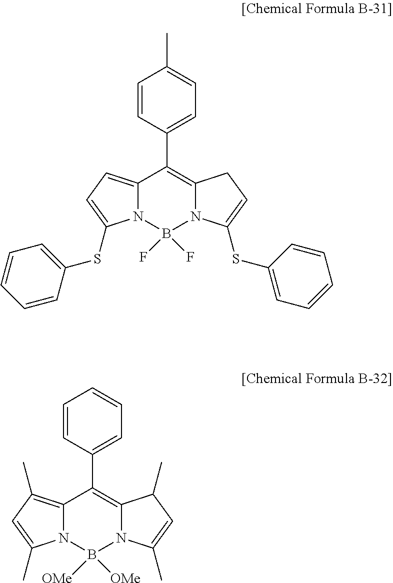

A first solvent according to the present invention may correspond to any one selected from the group consisting of an aqueous solvent, an alcohol-based solvent, a ketone-based solvent, an ether-based solvent, a sulfoxide-based solvent, an ester-based solvent, and mixtures thereof. Specifically, the first solvent may correspond to an anti-solvent having low solubility for the organic phosphor.

The organic phosphor according to the present invention is used differently in light emitting diodes and displays. When used in a light emitting diode, it may be preferable to use a phosphor having a delayed fluorescence property because it needs to have a wide full width at half maximum for a high color rendering index, and when used in a display, it may be preferable to use a boron compound or a phosphor having a fluorescence property because it needs to have a narrow full width at half maximum for high color purity.

Examples of the aqueous solvent may include any one selected from the group consisting of water, hydrochloric acid, aqueous sodium hydroxide solutions, and mixtures thereof, examples of the alcohol-based solvent may include any one selected from the group consisting of methanol, ethanol, isopropyl alcohol, n-propyl alcohol, 1-methoxy-2-propanol, and mixtures thereof, and examples of the ketone-based solvent may include any one selected from the group consisting of acetone, methyl ethyl ketone, methyl isobutyl ketone, cyclohexanone, and mixtures thereof. Examples of the ether-based solvent may include any one selected from the group consisting of dimethyl ether, diethyl ether, tetrahydrofuran, and mixtures thereof. Dimethyl sulfoxide may be typically used as the sulfoxide-based solvent, and an alkyl ester-based solvent may be typically used as the ester-based solvent. However, the technical idea of the present invention is not limited to the above types of solvent, and various solvents may be used.

The surfactant according to the present invention may correspond to any one selected from the group consisting of an anionic surfactant, a cationic surfactant, a zwitterionic surfactant, a nonionic surfactant, and mixtures thereof. For example, Triton X100 or TBAOleate may be typically used as the surfactant.

The anionic surfactant may correspond to a surfactant whose hydrophilic group exhibits an anion when dissolved in water. The hydrophilic group of the anionic surfactant may correspond to any one functional group selected from the group consisting of carboxylate, sulfate, sulfonate, and phosphate.

The cationic surfactant is a surfactant whose hydrophilic group exhibits a cation when dissolved in water, and may include a nitrogen atom having a positive charge. For example, tetrabutylammonium oleate (TBAOleate) may be used as the cationic surfactant.

The zwitterionic surfactant corresponds to a surfactant having properties of an anionic surfactant in an alkaline range and a cationic surfactant in an acidic range when dissolved in water.

The nonionic surfactant is a surfactant having a hydrophilic group that is not ionized when dissolved in water, and means a surfactant that has no charge even when dissolved in water. For example, Triton X100 may be used as the nonionic surfactant, and the Triton X100 has a hydrophilic polyethylene oxide chain and an aromatic hydrocarbon lipophilic or hydrophobic group.

The number of moles of the surfactant according to the present invention may be 20 to 1000 times, preferably 200 to 800 times, and more preferably 400 to 600 times based on the number of moles of the organic phosphor. In other words, the concentration of the surfactant on a laboratory scale may correspond to 0.2 mM to 10 mM, preferably 4 mM to 8 mM, and more preferably 5 mM to 7 mM. When the concentration of the surfactant is outside the above numerical range, a size of the light-emission type organic nanoparticle may be small and non-uniform.

When the surfactant is used and the concentration of the surfactant exceeds a critical micelle concentration, the hydrophobic portion of the surfactant surrounds the organic nanoparticles to form micelles, and the micelles are dispersed in the solvent. This uniformly forms the shape of all of the light-emission type organic nanoparticles and makes the particle size constant, so that the yield of the light-emission type organic nanoparticles increases. In addition, since the size of the light-emission type organic nanoparticle can be controlled by adjusting the concentration of the surfactant, the properties of the color conversion film can be improved.

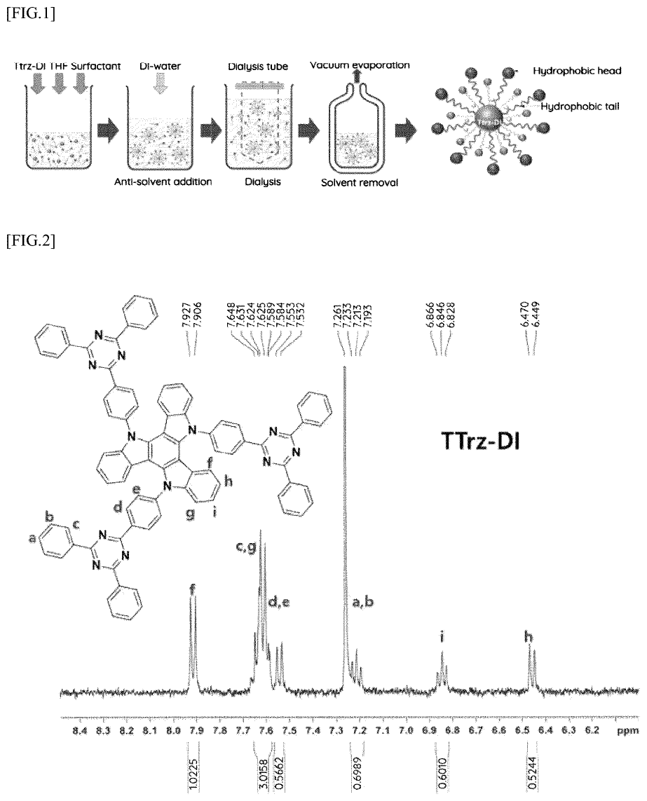

FIG. 1 shows a schematic diagram showing a method of preparing light-emission type organic nanoparticles (Ttrz-DI NPs) according to an embodiment of the present invention.

Referring to FIG. 1, a stock solution was prepared by dissolving a novel green phosphor (Ttrz-DI) in the first tetrahydrofuran (THF). The surfactant was also dissolved in a separate the second tetrahydrofuran (THF) to prepare a solution. A first mixture was prepared by adding the solution including the surfactant to the stock solution including the Ttrz-DI.

A dispersion solution was prepared by mixing the first mixture with deionized water. After filtering the dispersion solution through a filter, the resultant was put into a dialysis tube made of cellulose acetate and concentrated under vacuum to vacuum-evaporate the solvent. Thus, green organic nanoparticles, Ttrz-DI nanoparticles (hereinafter, referred to as Ttrz-DI NPs) were finally prepared.

Another embodiment of the present invention corresponds to light-emission type organic nanoparticles prepared by the method of preparing light-emission type organic nanoparticles. The descriptions overlapping with the foregoing content will be briefly described or omitted.

An average size of the light-emission type organic nanoparticle of the present invention may correspond to 100 to 170 nm (nanometers), preferably 110 to 160 nm, and more preferably 120 to 150 nm.

According to one embodiment of the present invention, the organic phosphor may be any one selected from the group consisting of a green phosphor, a blue phosphor, and a red phosphor.

According to one embodiment of the present invention, the organic phosphor is a delayed fluorescence material, and a luminescence efficiency may be 80% or more.

The delayed fluorescence material may be a compound represented by the above Chemical Formula 1.

The present invention may be characterized in that the delayed fluorescence material is any one of compounds represented by the above Chemical Formulas T-1 to T-32.

According to one embodiment of the present invention, the organic phosphor may be a phosphor having a luminescence efficiency of 80% or more and having a boron compound as a main structure.

The phosphor having a boron compound as a main structure may be a compound represented by the above Chemical Formula 2.

The present invention may be characterized in that the boron compound is any one of the compounds represented by the above Chemical Formulas D-1 to D-30.

According to another embodiment of the present invention, the phosphor having a boron compound as a main structure may be a compound represented by the above Chemical Formula 3. The present invention may be characterized in that the boron compound is any one of the compounds represented by the above Chemical Formulas B-1 to B-32.

The surfactant according to the present invention may be any one selected from the group consisting of an anionic surfactant, a cationic surfactant, a zwitterionic surfactant, a nonionic surfactant, and mixtures thereof.

The number of moles of the surfactant may be 20 to 1000 times based on the number of moles of the organic phosphor.

The light-emission type organic nanoparticles prepared by the method of preparing light-emission type organic nanoparticles according to the present invention may have a small and uniform size. When the size of the light-emission type organic nanoparticle is small and uniform, the yield of the light-emission type organic nanoparticle may be increased.

### 2. Composition for Color Conversion Film

A composition for a color conversion film according to the present invention includes a polymer resin, and 2 to 20 parts by weight of the light-emission type organic nanoparticles based on 100 parts by weight of the polymer resin. When a content of the light emitting organic nanoparticles is less than the above numerical range, an amount of light-emitting particles may be insufficient, resulting in a decrease in color conversion efficiency, and when the content exceeds the above numerical range, aggregation between nanoparticles becomes strong, and thus a particle size increases and quenching may occur.

The polymer resin according to the present invention may correspond to any one selected from the group consisting of polymethyl methacrylate, polyvinyl alcohol, polyvinyl pyrrolidone, polycarbonate, and mixtures thereof, and preferably polyvinyl alcohol. However, the technical idea of the present invention is not limited to the above types of polymer resin, and any polymer resin applicable to the color conversion film may be used.

### 3. Method of Manufacturing Color Conversion Film and Color Conversion Film Manufactured Thereby

Still another embodiment of the present invention for achieving the above objects corresponds to a method of manufacturing a color conversion film, including applying the composition for a color conversion film on a substrate.

A method of manufacturing a color conversion film according to the present invention may include drying the composition for a color conversion film applied on the substrate. Specifically, the step of drying the composition for a color conversion film may be a step of annealing the composition for a color conversion film at 40 to 60° C. for 4 to 6 hours, and through this, the solvent in the composition for a color conversion film may be dried or removed.

Yet another embodiment of the present invention corresponds to a color conversion film manufactured by the method of manufacturing a color conversion film.

The color conversion film according to the present invention may have a thickness of 100 to 200 μm (micrometers), preferably 110 to 180 μm, and more preferably 120 to 150 μm.

### 4. Display Device

Yet another embodiment of the present invention corresponds to a display device including the color conversion film. The descriptions overlapping with the foregoing content will be briefly described or omitted.

The display device according to the present invention may correspond to a liquid crystal display device.

Since the organic phosphor used in the display device needs to have a narrow full width at half maximum for high color purity, it is preferable that the organic phosphor is the above-described phosphor having a luminescence efficiency of 80% or more and having a boron compound as a main structure or a phosphor having a fluorescence property.

In general, the display device includes two display panels. Specifically, the liquid crystal display includes a lower display panel including thin film transistors and an upper display panel facing the lower display panel, and the organic light emitting device includes a lower display panel including a thin film transistor and an emission layer and an upper display panel facing the lower display panel.

The display device according to the present invention may include a base film, a reflective layer, and the color conversion film on a substrate.

Specifically, the base film may block light while having a plurality of openings. For example, the base film is a black-based film and may correspond to a black polyester film or a black polyurethane film containing carbon black. However, the technical idea of the present invention is not limited thereto, and any film capable of blocking light and having excellent thermal properties may be used.

The color conversion film according to the present invention may be disposed in the opening, have patterns of different colors, absorb a portion of incident light, and emit light having a wavelength different from that of the absorbed light.

The reflective layer according to the present invention may be disposed on a side surface of the opening.

### 5. Light Emitting Diode Device

Yet another embodiment of the present invention corresponds to a light emitting diode device including the color conversion film. The descriptions overlapping with the foregoing content will be briefly described or omitted.

The light emitting diode device is a light emitting device that emits light by applying a voltage to a PN junction diode of a compound semiconductor, and corresponds to a light emitting device that emits energy in the form of light when holes and electrons move between p-n and combine with each other.

The light-emission type organic nanoparticles used in the light emitting diode device need to have a wide full width at half maximum (FWHM) to realize a high color rendering index (CRI). Accordingly, the organic phosphor used in the light emitting diode device is preferably the above-described delayed fluorescence material having a wide half width at half maximum for a high color rendering index and having a luminescence efficiency of 80% or more.

In general, the light emitting diode devices are classified into chip LEDs having characteristics of high luminous intensity, and being ultra-small and thin, top LEDs, and lamp LEDs used for outdoor displays or electric signboards with ultra-high luminous intensity and high moisture resistance and heat resistance, depending on the purpose of use.

The light emitting diode device according to the present invention may include a substrate, and an LED chip disposed on the substrate. The color conversion film according to the present invention can absorb light emitted from the LED chip (or LED backlight) and convert it into light of a different wavelength. The substrate may correspond to, for example, n-GaAs.

Hereinafter, examples of the present invention will be described in more detail so that those skilled in the art can easily practice it, but this is only one example, and the scope of the present invention is not limited thereto.

### Manufacturing Preparation Example 1: Synthesis of Novel Green Phosphor Material (Chemical Formula T-3)

A 3:1 molar ratio mixture of 2-(4-bromophenyl)-4,6-diphenyl-1,3,5-triazine (Trz, 8.85 mmol) and 10,15-dihydro-5H-diindolo[3,2-a:3′,2′-c]carbazole (fused carbazole, 2.95 mmol) was added into a mixture of tris(dibenzylideneacetone)dipalladium(0) (Pd₂(dba)₃, 0.08 mmol), tri-tert-butylphosphine ((t-Bu)₃P, 1.86 mmol), sodium tert-butoxide (NaOtBu, 5.15 mmol), and anhydrous o-xylene. The mixture to which Trz and fused carbazole were added was flushed with nitrogen, and an inert atmosphere was created under vacuum conditions. Thereafter, the reaction proceeded constantly while refluxing at 135° C. for 12 hours. The reaction mixture was cooled, and washed several times with dichloromethane and deionized water. Water was discarded from the washed mixture and the dichloromethane layer was dried over anhydrous sodium sulfate. The dried mixture was filtered through a filter, and the remaining solvent was evaporated using a rotary evaporator to obtain a final product purified by silica column chromatography, 5,10,15-tris(4-(4,6-diphenyl-1,3,5-triazin-2-yl)phenyl)-10,15-dihydro-5H-diindolo[3,2-a:3′,2′-c]carbazole (hereinafter, referred to as Ttrz-DI).

Summarizing the reaction in which the final product is generated may proceed as shown in Scheme 1 below.

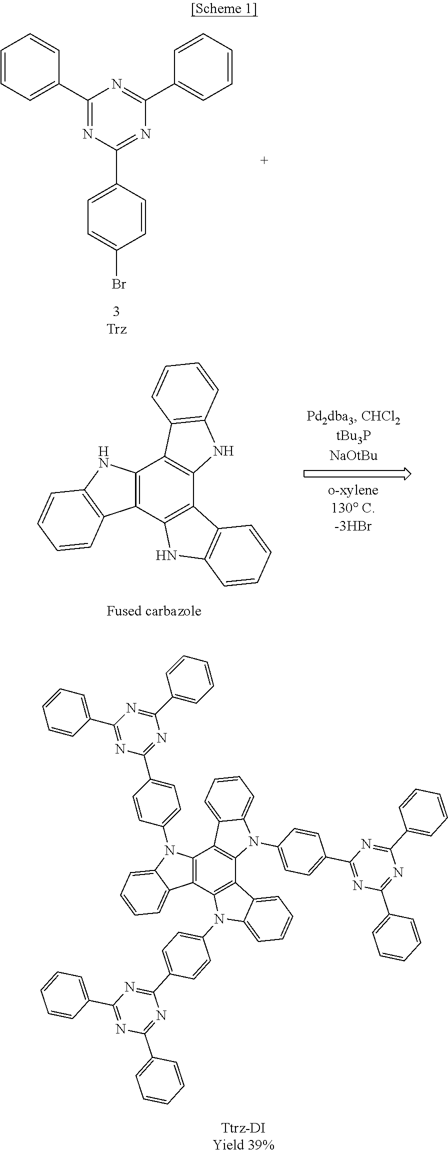 [SMILES: Brc1ccc(-c2nc(-c3ccccc3)nc(-c3ccccc3)n2)cc1 ; c1ccc2c(c1)[nH]c1c2c2[nH]c3ccccc3c2c2[nH]c3ccccc3c12 ; c1ccc(-c2nc(-c3ccccc3)nc(-c3ccc(-n4c5ccccc5c5c4c4c6ccccc6n(-c6ccc(-c7nc(-c8ccccc8)nc(-c8ccccc8)n7)cc6)c4c4c6ccccc6n(-c6ccc(-c7nc(-c8ccccc8)nc(-c8ccccc8)n7)cc6)c54)cc3)n2)cc1]

### Experimental Example 1-1: ¹H NMR Data of the Novel Green Phosphor

FIG. 2 shows the ¹H NMR data of the novel Ttrz-DI. The ¹H NMR data was measured using a 400 MHz Bruker NMR spectrometer.

Referring to FIG. 2, it can be seen that Ttrz-DI is generated by reacting Trz and fused carbazole in a molar ratio of 3:1, respectively.

### Experimental Example 1-2: Photophysical Characteristic Analysis Experiment of the Novel Green Phosphor

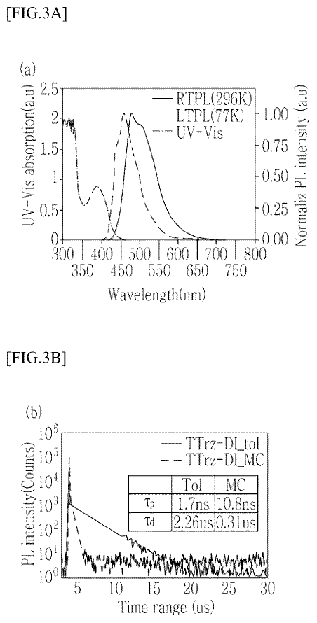

FIG. 3A shows the UV-Vis, room temperature photoluminescence (RTPL), and low temperature photoluminescence (LTPL) spectra of Ttrz-DI in toluene.

Referring to FIG. 3A, an initial value of a luminescence intensity at room temperature (hereinafter, referred to as RTPL) indicates that energy in a singlet state of Ttrz-DI is about 2.11 eV, and an initial value of a luminescence intensity at a low temperature (hereinafter, referred to as LTPL) in a 77K toluene solution indicates that energy in a triplet state of Ttrz-DI is 2.34 eV. Therefore, the energy difference between in the triplet state and in the singlet state of Ttrz-DI corresponds to 0.23 eV.

FIG. 3B shows the time resolved photoluminescence (TRPL) of Ttrz-DI in a solvent. A y-axis of FIG. 3B is a PL intensity (counts). The solvent is toluene (Tol) or dichloromethane (MC).

Referring to FIG. 3B, it can be seen that Ttrz-DI has thermally activated delayed fluorescence (TADF) characteristics by seeing that it has two decays, a prompt decay and a delayed decay.

### Preparation Example 1: Preparation of Light-Emission Type Organic Nanoparticles

### Example 1-1

A stock solution (0.5 mM) was prepared by dissolving the green phosphor Ttrz-DI (0.5 M, 0.1 mL) in the first tetrahydrofuran. A surfactant (Triton X-100) was also dissolved in a separate second tetrahydrofuran (THF) to prepare a solution (0.1 M). The first mixture was prepared by adding the solution including the surfactant to the stock solution (1 mL) including the Ttrz-DI. A dispersion was prepared by mixing the first mixture with deionized water. After filtering the dispersion through a 0.2 μm filter, the resultant was put into a dialysis tube made of cellulose acetate and concentrated under vacuum to vacuum-evaporate the solvent for 12 hours. Thus, green organic nanoparticles, Ttrz-DI nanoparticles (hereinafter, referred to as Ttrz-DI NPs) were finally prepared.

### Example 1-2

Ttrz-DI NPs were prepared in the same manner as in Example 1-1 except that tert-butyl ammonium oleate (TBAOleate) was used instead of Triton X-100 as a surfactant.

### Example 1-3

Light-emission type organic nanoparticles were prepared in the same manner as in Example 1-1 except that a compound (4CzIPN (1,2,3,5-tetrakis(carbazol-9-yl)-4,6-dicyanobenzene, 2,4,5,6-tetrakis(9H-carbazol-9-yl) isophthalonitrile)) represented by Chemical Formula T-9, which is another green phosphor, was used instead of the green phosphor according to Example 1-1.

### Example 2-1

Organic nanoparticles were prepared in the same manner as in Example 1-1 except that a compound (CzDABNA(2,12-di-tert-butyl-N,N,5,9-tetrakis(4-(tert-butyl)phenyl)-5,9-dihydro-5,9-diaza-13b-boranaphtho[3,2,1-de]anthracen-7-amine)) represented by Chemical Formula D-13, which is a blue phosphor, was used instead of the green phosphor.

### Example 2-2

Organic nanoparticles were prepared in the same manner as in Example 2-1 except that tert-butyl ammonium oleate (TBAOleate) was used instead of Triton X-100 as a surfactant.

### Example 3-1

Light-emission type organic nanoparticles were prepared in the same manner as in Example 1-1 except that a compound (4tBuMB (1,3,7,9-tetrakis(4-(tert-butyl)phenyl)-5,5-difluoro-10-(2-methoxyphenyl)-5H-4l4,5l4-dipyrrolo[1,2-c:2′,1′-f][1,3,2]diazaborinine)) represented by Chemical Formula B-23, which is a red phosphor, was used instead of the green phosphor.

### Example 3-2

Light-emission type organic nanoparticles were prepared in the same manner as in Example 3-1 except that tert-butyl ammonium oleate (TBAOleate) was used instead of Triton X-100 as a surfactant.

### Comparative Example 1

Organic nanoparticles were prepared in the same manner as in Example 1-1 except that no surfactant was used.

### Experimental Example 2: Size and Shape Analysis of Light-Emission Type Organic Nanoparticles

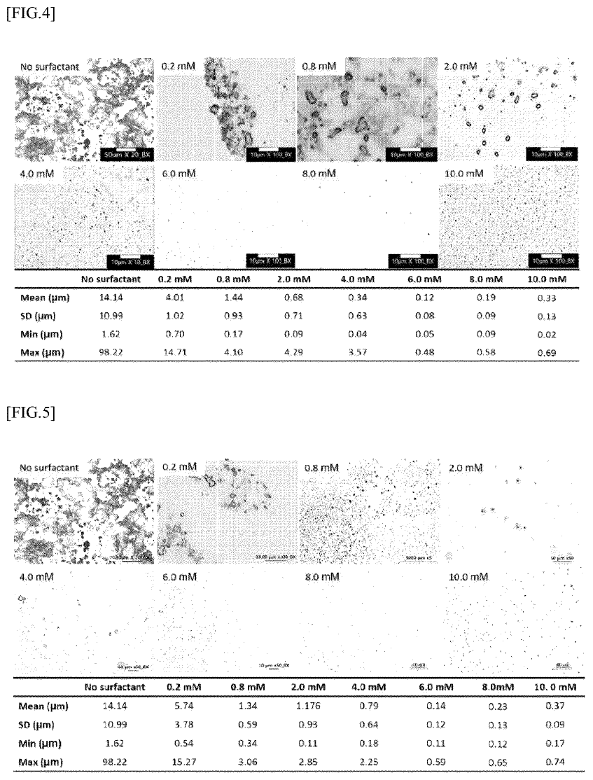

FIG. 4 shows optical micrographs of organic nanoparticles in the absence of TritonX-100 (Comparative Example 1) and in the case of varying the concentration of TritonX-100 from 0.2 mM to 10.0 mM, when the organic nanoparticles are prepared by the method of preparing light-emission type organic nanoparticles according to Example 1-1.

Referring to FIG. 4, it can be seen that the size of the light-emitting organic nanoparticles becomes uniform and smaller as the concentration of a surfactant TritonX-100 converges to 6.0 mM.

FIG. 5 shows optical micrographs of organic nanoparticles in the absence of TBAOleate (Comparative Example 1) and in the case of varying the concentration of TBAOleate from 0.2 mM to 10.0 mM, when the organic nanoparticles are prepared by the method of preparing light-emission type organic nanoparticles according to Example 1-2.

Referring to FIG. 5, as with TritonX-100, it can be seen that the size of the light-emission type organic nanoparticle becomes uniform and smaller as the concentration of TBAOleate converges to 6.0 mM.

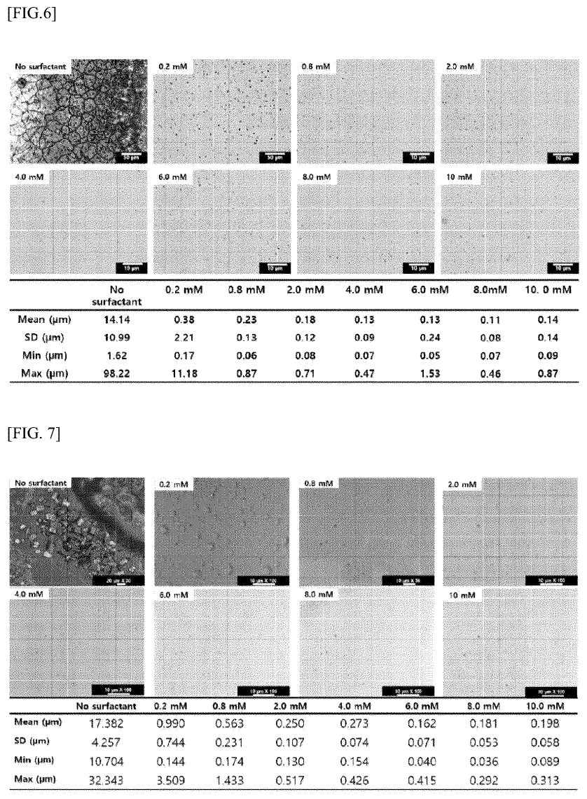

FIG. 6 shows optical micrographs of organic nanoparticles in the absence of TritonX-100 (Comparative Example 1) and in the case of varying the concentration of TritonX-100 from 0.2 mM to 10.0 mM, when the organic nanoparticles are prepared by the method of preparing light-emission type organic nanoparticles according to Example 2-1.

Referring to FIG. 6, it can be seen that when the concentration of TritonX-100 is 8.0 mM, the average size of the generated organic nanoparticles is the smallest, and when the concentration of TritonX-100 is 4.0 mM to 8.0 mM, the average size of the generally generated organic nanoparticles is as small as 0.11 to 0.13 μm.

FIG. 7 shows optical micrographs of organic nanoparticles in the absence of TritonX-100 (Comparative Example 1) and in the case of varying the concentration of TritonX-100 from 0.2 mM to 10.0 mM, when red organic nanoparticles are prepared by the method of preparing light-emission type organic nanoparticles according to Example 3-1.

Referring to FIG. 7, in general, it can be seen that the size of a red organic nanoparticle becomes uniform and smaller as the concentration of a surfactant TritonX-100 converges to 6.0 mM.

### Experimental Example 3: Luminescence Intensity That Varies Depending on the State of Ttrz-DI

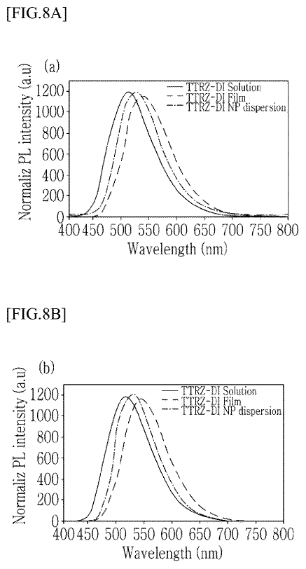

FIG. 8A shows the case when a surfactant is Triton X-100, when Ttrz-DI is in solution, is a film, and is dispersed in a dispersion solution in the order from left to right.

FIG. 8B shows the case when a surfactant is TBAOleate, when Ttrz-DI is in solution, is a film, and is dispersed in a dispersion solution in the order from left to right.

As control variables in Experimental Example 3, the concentration of the surfactant was set to 6 mM, the concentration of the organic phosphor was set to 0.01 mM, the size of a filter was set to 0.2 μm, the solvent was set to THF, and the anti-solvent was set to deionized water.

Referring to FIGS. 8A and 8B, it can be seen that a position of a peak varies depending on a Ttrz-DI state. This difference occurs as the size of the organic nanoparticle varies. Specifically, when Ttrz-DI is in a solution state, the organic nanoparticles have a size distribution of the Angstrong(Å) size unit, and the particles form a large aggregation in a bulk film state.

In contrast, when Ttrz-DI is in a dispersion solution, it can be inferred that a peak is located between a solution and a film because the size of the particle is uniformly distributed as a micro or nanometer size unit.

### Experimental Example 4: Experiment to Derive Luminescence Intensity and Optimal Surfactant Concentration According to Concentration Change of Surfactant

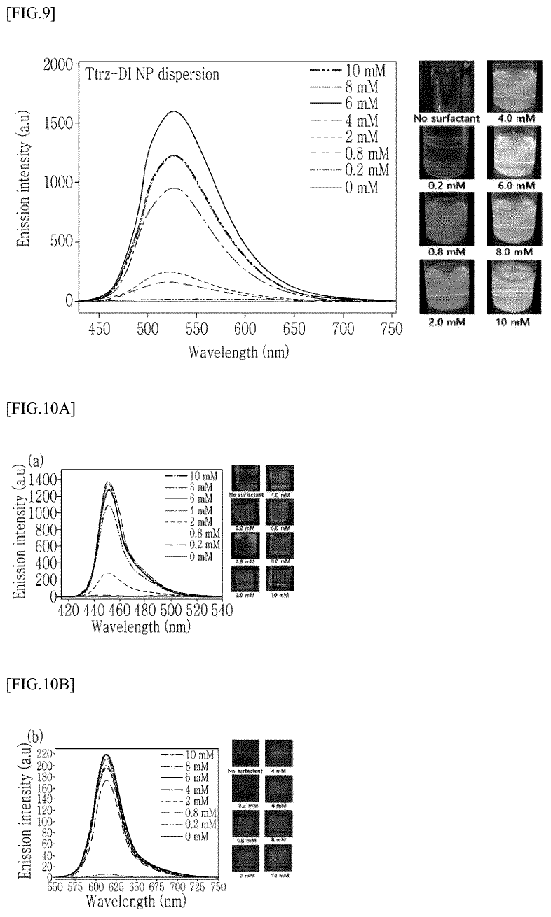

FIG. 9 shows a luminescence intensity in the absence of a surfactant and in the case where the concentration of the surfactant was varied from 0.2 mM to 10 mM, on the premise that 0.01 mM of Ttrz-DI was added, when light-emission type organic nanoparticles are prepared by the preparation method according to Example 1-1.

Referring to FIG. 9, it can be seen that when the concentration of Triton X-100 used as a surfactant exceeds 6 mM, the luminescence intensity decreases, and when the concentration is less than 6 mM, the luminescence intensity also decreases. That is, it can be seen that the strongest peak is exhibited when a concentration of Triton X-100 is 6 mM, and the present inventors derived an optimal concentration range of the surfactant through this.

This means that the smallest Ttrz-DI NP can be synthesized when the concentration of Triton X-100 is 6 mM, and the same results as in Experimental Example 2 were obtained.

FIG. 10A shows a luminescence intensity of the light-emission type organic nanoparticles in the absence of a surfactant and in the case where the concentration of the surfactant was varied from 0.2 mM to 10 mM, on the premise that 0.01 mM of CzDABNA was added, when light-emission type organic nanoparticles are prepared by the preparation method according to Example 2-1.

FIG. 10B shows a luminescence intensity of the light-emission type organic nanoparticles in the absence of a surfactant and in the case where the concentration of the surfactant (Triton X-100) was varied from 0.2 mM to 10 mM, on the premise that 0.01 mM of 4tBuMB was added, when light-emission type organic nanoparticles are prepared by the preparation method according to Example 3-1.

Referring to FIG. 10A, the results similar to those of FIG. 9 were obtained, and CzDABNA NPs exhibited a maximum luminescence intensity when the concentration of the surfactant was 4 mM, and referring to FIG. 10B, 4tBuMB NPs showed a maximum luminescence intensity at 8 to 10 mM.

### Experimental Example 5: Size Measurement Experiment Through the Yield of Light-Emission Type Organic Nanoparticles

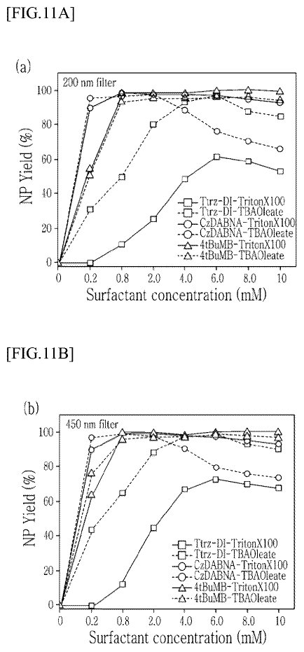

FIG. 11A shows the yield of organic nanoparticles having an average size of less than 200 nm according to the concentration of a surfactant.

FIG. 11B shows the yield of organic nanoparticles having an average size of less than 450 nm according to the concentration of a surfactant.

Referring to FIG. 11A, when the concentrations of Triton X100 or TBAOleate used as a surfactant were varied from 0 to 10 mM, the most of yields were close to yields of 80 to 100% except for the light-emitting organic nanoparticles prepared by mixing Ttrz-DI and Triton X100 (Example 1-1) and the light-emitting organic nanoparticles prepared by mixing CzDABNA and TBAOleate (Example 2-2). Meanwhile, the light-emission type organic nanoparticles according to Example 3-2 were close to 100% yield.

Referring to FIG. 11B, as in the result of FIG. 11A, the most of yields were close to yields of 85 to 100% except for the light-emitting organic nanoparticles prepared by mixing Ttrz-DI and Triton X100 (Example 1-1) and the light-emitting organic nanoparticles prepared by mixing CzDABNA and TBAOleate (Example 2-2).

The results of the characteristics of the organic nanoparticles prepared according to Experimental Examples 2 and 5 are summarized in Table 1.

TABLE 1

| | | Full width | Photo- | |
|---|---|---|---|---|
| | Maximum | at half | luminescence | Average |
| | luminescence | maximum | quantum yield | nanoparticle |
| | spectrum | (FWHM) | (PLQY) | size |
| Example 1-1 | 517 nm | 91 nm | 0.43 | 120 nm |
| Example 1-3 | 513 nm | 63 nm | 0.77 | 130 nm |
| Example 2-1 | 454 nm | 20 nm | 0.39 | 110 nm |
| Example 3-1 | 621 nm | 31 nm | 0.99 | 162 nm |
| QD | 525 nm | 35 nm | 0.70 | <20 nm |

### Preparation Example 2: Manufacture of Color Conversion Film Using Light-Emission Type Organic Nanoparticles

### Example 4

1 g of polyvinyl alcohol (weight average molecular weight of 13000 to 23000 g/mol, hydration degree of 87 to 89%) was dissolved in 9 g of deionized water to prepare a 10 weight % aqueous polyvinyl alcohol solution. Light-emission type organic nanoparticles (0.3 g of dispersion solution) according to Example 1-1 were mixed with the aqueous polyvinyl alcohol solution (2.7 g). After uniformly spraying the mixed solution (3 ml) on a 4 cm×4 cm plastic frame, annealing was performed in an oven at 60° C. for 4 hours to remove the solvent and prepare a color conversion film. The thickness of the color conversion film was measured using a digital vernier caliper and was 160 nm.

### Example 5

A color conversion film was prepared in the same manner as in Example 4 except that the light-emission type organic nanoparticles according to Example 2-1 were used instead of the light-emission type organic nanoparticles according to Example 1-1.

### Example 6

A color conversion film was prepared in the same manner as in Example 4 except that the light-emission type organic nanoparticles according to Example 3-1 were used instead of the light-emission type organic nanoparticles according to Example 1-1.

### Example 7

A color conversion film was prepared in the same manner as in Example 4 except that the light-emission type organic nanoparticles according to Example 1-3 were used instead of the light-emission type organic nanoparticles according to Example 1-1.

### Comparative Example 2

A color conversion film including InP/ZnSe/ZnS-based quantum dots (QDs), which are inorganic green light emitting particles, was prepared on a poly(methyl methacrylate) host.

### Experimental Example 6: Color Conversion Efficiency of Color Conversion Film

The optical properties of the color conversion films according to Examples 4 to 7 were evaluated, and specifically, an UV-Vis absorption spectrum and a photoluminescence spectrum at room temperature were measured. The UV-Vis absorption spectrum was measured using JASCO V-750, and the photoluminescence spectrum at room temperature was measured using a JASCO-FP 8500 instrument. An absolute photoluminescence quantum yield (PLQY) value and color conversion efficiency were measured using an integrating sphere built into the JASCO-FP 8500 equipment.

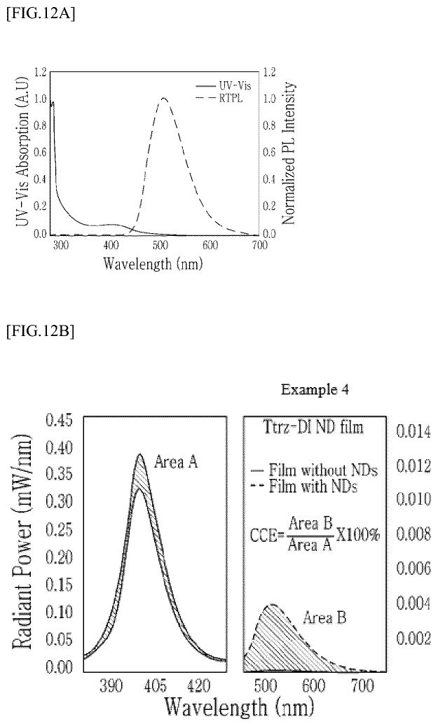

FIG. 12A shows the optical properties of the color conversion film according to Example 4.

FIG. 12B shows a method for measuring the color conversion efficiency of the color conversion film according to Example 4.

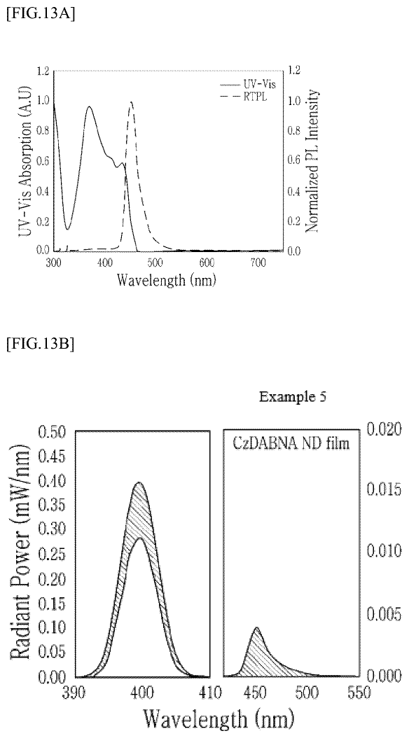

FIG. 13A shows the optical properties of the color conversion film according to Example 5.

FIG. 13B shows a method for measuring the color conversion efficiency of the color conversion film according to Example 5.

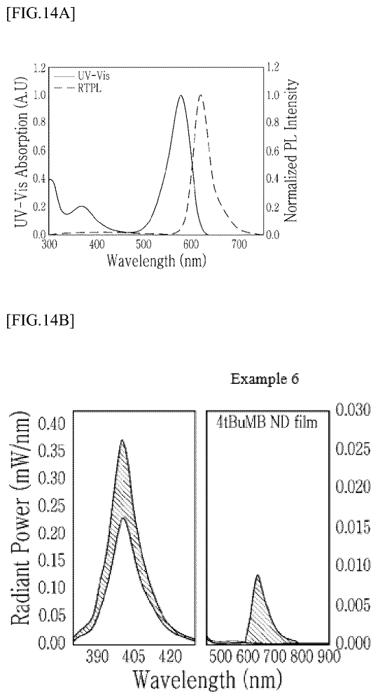

FIG. 14A shows the optical properties of the color conversion film according to Example 6.

FIG. 14B shows a method for measuring the color conversion efficiency of the color conversion film according to Example 6.

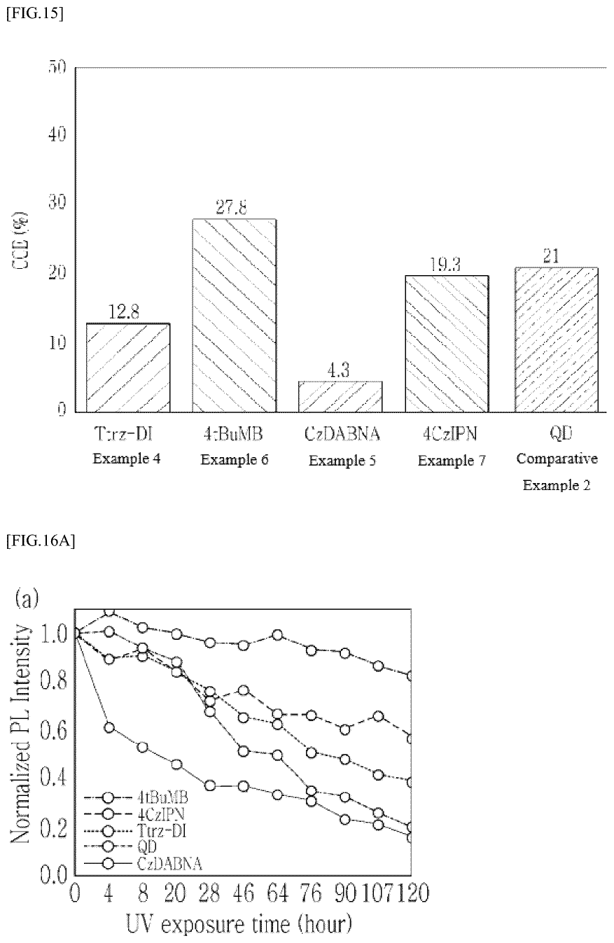

FIG. 15 shows the color conversion efficiency of color conversion films according to Examples 4 to 7 and Comparative Example 2. The results are summarized in Table 2 below.

Specifically, as a method for measuring color conversion efficiency, the color conversion film according to Example 4 of FIG. 12B will be described as an example. The ratio (%) of a green light emitting region (B) to the blue light emitting region (A) corresponds to the color conversion efficiency, the blue light emitting region (A) means blue incident light absorbed by the color conversion film, and the green light emitting region (B) means a green emitting region emitted by the color conversion film.

Referring to FIGS. 12 to 15, it can be seen that the color conversion efficiency of the color conversion film according to Example 6 is the highest, and the color conversion efficiency of the color conversion film according to Example 7 is equivalent to that of Comparative Example 2.

TABLE 2

| | | Full width | Photo- | Color |
|---|---|---|---|---|
| | Maximum | at half | luminescence | conversion |
| | luminescence | maximum | quantum yield | efficiency |
| | spectrum | (FWHM) | (PLQY) | (CCE; %) |
| Example 4 | 5ll nm | 83 nm | 0.86 | 12.8 |
| Example 5 | 452 nm | 25 nm | 0.43 | 4.3 |
| Example 6 | 619 nm | 39 nm | 0.99 | 27.8 |
| Example 7 | 506 nm | 72 nm | 0.95 | 19.3 |
| Comparative | 525 nm | 35 nm | 0.28 | 21.0 |
| Example 2 | | | | |

### Experimental Example 7: UV Stability Test of Color Conversion Film and Durability Test of Color Conversion Efficiency

For each of the color conversion films according to Examples 4 to 7 and Comparative Example 2, a UV stability test and a color conversion efficiency durability test were evaluated.

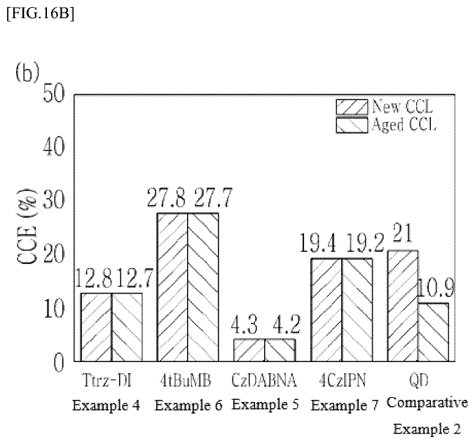

FIG. 16A shows a luminescence intensity obtained by measuring a luminescence spectrum at room temperature over time when color conversion films according to Examples 4 to 7 and Comparative Example 2 were continuously exposed to UV (wavelength: 365 nm) for 120 hours. The stability test for the UV was measured using JASCO-FP 8500 equipment.

Referring to FIG. 16A, it can be seen that the color conversion film according to Example 6 is the most stable against UV, and it can be seen that the color conversion film according to Example 7, the color conversion film according to Example 4, and the color conversion film according to Comparative Example 2 are stable against UV in this order.

FIG. 16B shows a change amount (%) in color conversion efficiency of each of the newly prepared color conversion films according to Examples 4 to 7 and Comparative Example 2 after being allowed to stand for one month. The color conversion efficiency was measured in the same manner as described above.

Referring to FIG. 16B, the color conversion film according to Comparative Example 2 showed a change in color conversion efficiency of 24% or more, and showed significantly poor color conversion efficiency durability. In contrast, each of the color conversion films according to Examples 4 to 7 differed in color conversion efficiency by less than 1%, indicating that the durability of the color conversion efficiency was excellent.

Although preferred embodiments of the present invention have been described in detail, the scope of the rights of the present invention is not limited thereto, and various modifications and improvements made by those skilled in the art using the basic concept of the present invention defined in the following claims also fall within the scope of the present invention.

1. A method of preparing light-emission type organic nanoparticles, comprising:
(S1) preparing a first mixture by mixing an organic phosphor and a surfactant; and
(S2) preparing a dispersion solution by mixing the first mixture with the first solvent which is an anti-solvent for the organic phosphor.

2. The method of claim 1, further comprising dialyzing the dispersion solution and drying the dialyzed dispersion solution.

3. The method of claim 1, wherein the organic phosphor is any one selected from the group consisting of a green phosphor, a blue phosphor, and a red phosphor.

4. The method of claim 1, wherein the organic phosphor is a delayed fluorescence material and has a luminescence efficiency of 80% or more.

5. The method of claim 4, wherein the delayed fluorescence material is a compound represented by Chemical Formula 1 below: 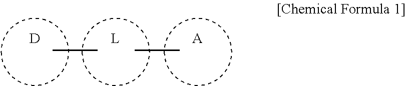
in Chemical Formula 1,
L is any one selected from the group consisting of an aryl group, an arylene group, and a carbon-nitrogen single bond,
when L is an aryl group, A is a cyano group mono- or di-substituted on the aryl group, and D is a substituent tetra- or penta-substituted on the aryl group, wherein each of the substituents is independently a heteroaryl group containing a nitrogen atom substituted with a hydrocarbon group having 1 to 10 carbon atoms,
when L is an arylene group, A is a substituted or unsubstituted triazine group, D is a substituted or unsubstituted heteroaryl group, includes a conjugated or non-conjugated 5-membered or 6-membered ring containing a nitrogen atom bonded to the arylene group, is a multi-fused ring conjugated with the conjugated or non-conjugated 5-membered or 6-membered ring, and includes 1 to 9 nitrogen atoms or one Group 16 element in the multi-fused ring, and
when L is a carbon-nitrogen single bond, D is a fused ring having 10 to 40 carbon atoms, includes a conjugated or non-conjugated 5-membered or 6-membered ring containing a nitrogen atom of L, includes a substituted or unsubstituted aryl group forming a fused ring with the conjugated or non-conjugated 5-membered or 6-membered ring, wherein the conjugated or non-conjugated 5-membered or 6-membered ring is a substituted or unsubstituted ring, does not include or includes a Group 16 element in the ring, and includes 1 or 2 nitrogen atoms in the ring, A is a heterocyclic ring having 15 to 40 carbon atoms, includes an aryl group containing a carbon atom bonded to L, includes a ring structure containing a boron atom and an oxygen atom in the ring, forming a fused ring with the aryl group containing the carbon atom, or includes a conjugated 5-membered or 6-membered ring structure containing two nitrogen atoms.

6. The method of claim 5, wherein the delayed fluorescence material is any one of compounds represented by the following Chemical Formulas T-1 to T-32:

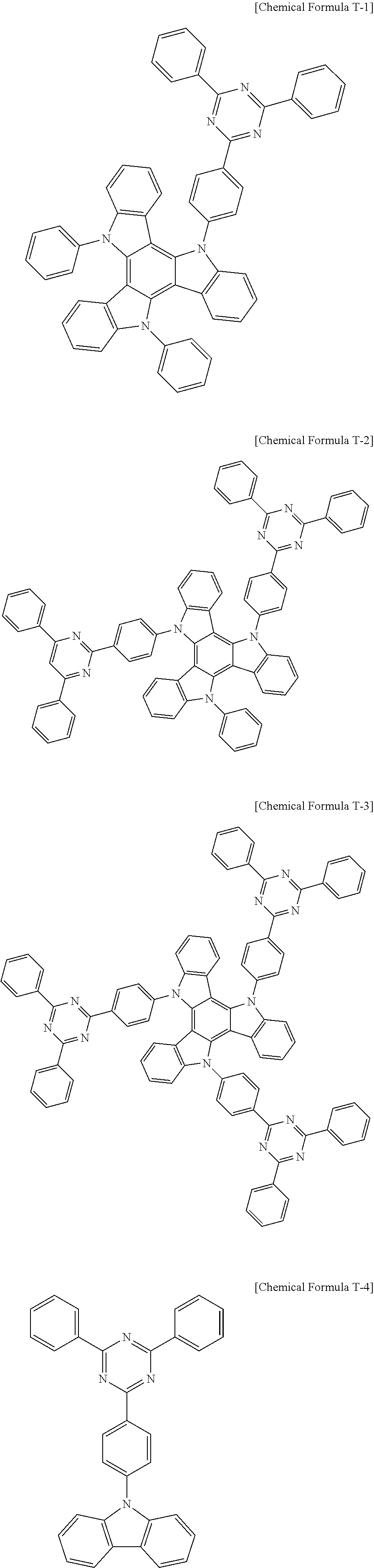 [SMILES: c1ccc(-c2nc(-c3ccccc3)nc(-c3ccc(-n4c5ccccc5c5c6c(c7ccccc7n6-c6ccccc6)c6c(c7ccccc7n6-c6ccccc6)c54)cc3)n2)cc1 ; c1ccc(-c2cc(-c3ccccc3)nc(-c3ccc(-n4c5ccccc5c5c4c4c6ccccc6n(-c6ccccc6)c4c4c6ccccc6n(-c6ccc(-c7nc(-c8ccccc8)nc(-c8ccccc8)n7)cc6)c45)cc3)n2)cc1 ; c1ccc(-c2nc(-c3ccccc3)nc(-c3ccc(-n4c5ccccc5c5c4c4c6ccccc6n(-c6ccc(-c7nc(-c8ccccc8)nc(-c8ccccc8)n7)cc6)c4c4c6ccccc6n(-c6ccc(-c7nc(-c8ccccc8)nc(-c8ccccc8)n7)cc6)c54)cc3)n2)cc1 ; c1ccc(-c2nc(-c3ccccc3)nc(-c3ccc(-n4c5ccccc5c5ccccc54)cc3)n2)cc1]

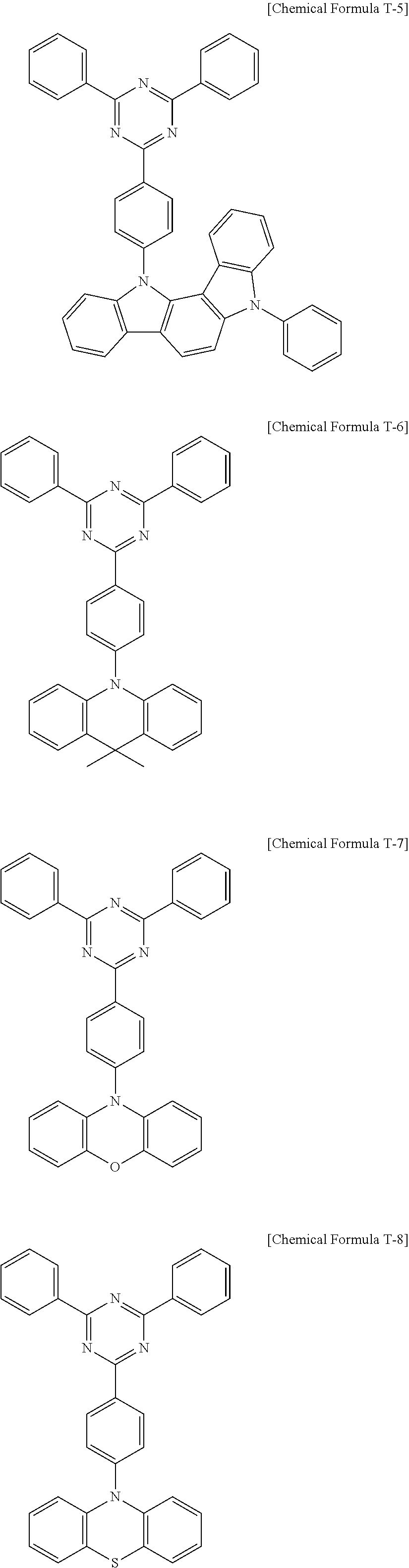 [SMILES: c1ccc(-c2nc(-c3ccccc3)nc(-c3ccc(-n4c5ccccc5c5ccc6c(c7ccccc7n6-c6ccccc6)c54)cc3)n2)cc1 ; CC1(C)c2ccccc2N(c2ccc(-c3nc(-c4ccccc4)nc(-c4ccccc4)n3)cc2)c2ccccc21 ; c1ccc(-c2nc(-c3ccccc3)nc(-c3ccc(N4c5ccccc5Oc5ccccc54)cc3)n2)cc1 ; c1ccc(-c2nc(-c3ccccc3)nc(-c3ccc(N4c5ccccc5Sc5ccccc54)cc3)n2)cc1]

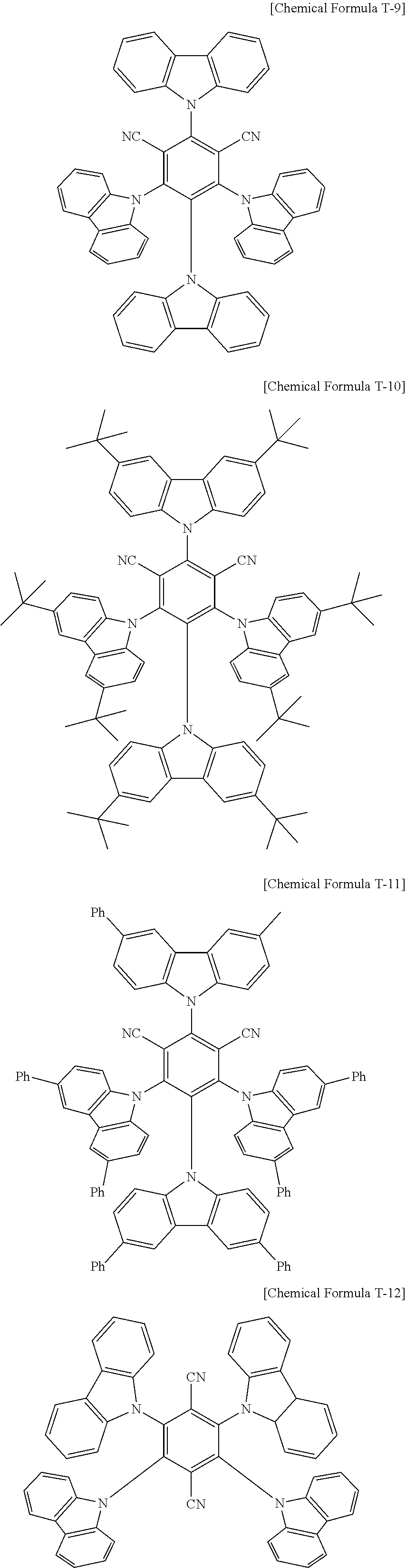

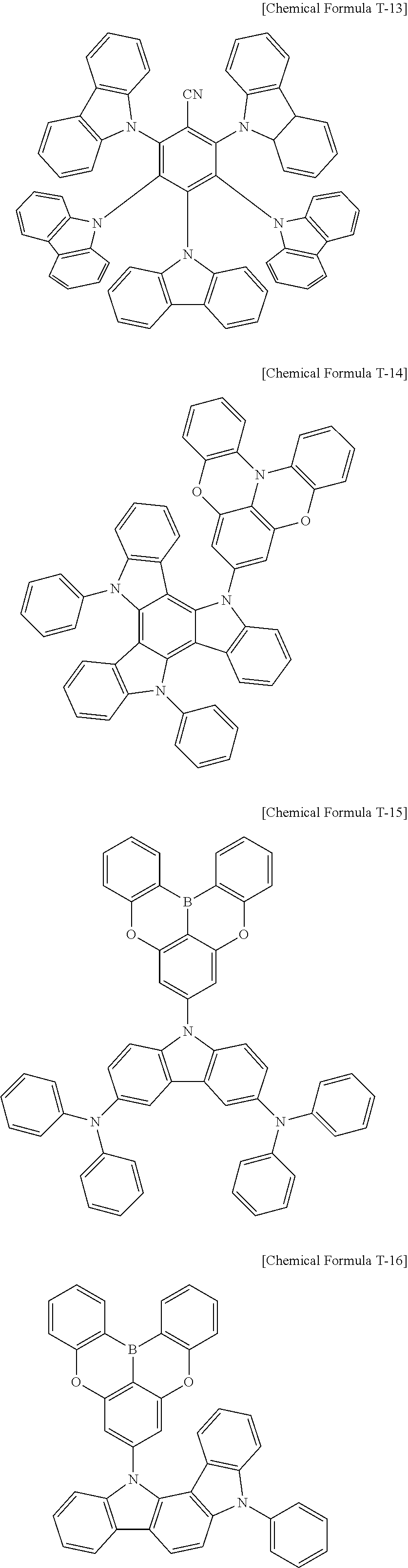 [SMILES: N#Cc1c(N2c3ccccc3C3C=CC=CC32)c(-n2c3ccccc3c3ccccc32)c(-n2c3ccccc3c3ccccc32)c(-n2c3ccccc3c3ccccc32)c1-n1c2ccccc2c2ccccc21 ; c1ccc(-n2c3ccccc3c3c2c2c4ccccc4n(-c4cc5c6c(c4)Oc4ccccc4N6c4ccccc4O5)c2c2c4ccccc4n(-c4ccccc4)c32)cc1 ; c1ccc(N(c2ccccc2)c2ccc3c(c2)c2cc(N(c4ccccc4)c4ccccc4)ccc2n3-c2cc3c4c(c2)Oc2ccccc2B4c2ccccc2O3)cc1 ; c1ccc(-n2c3ccccc3c3c2ccc2c4ccccc4n(-c4cc5c6c(c4)Oc4ccccc4B6c4ccccc4O5)c23)cc1]

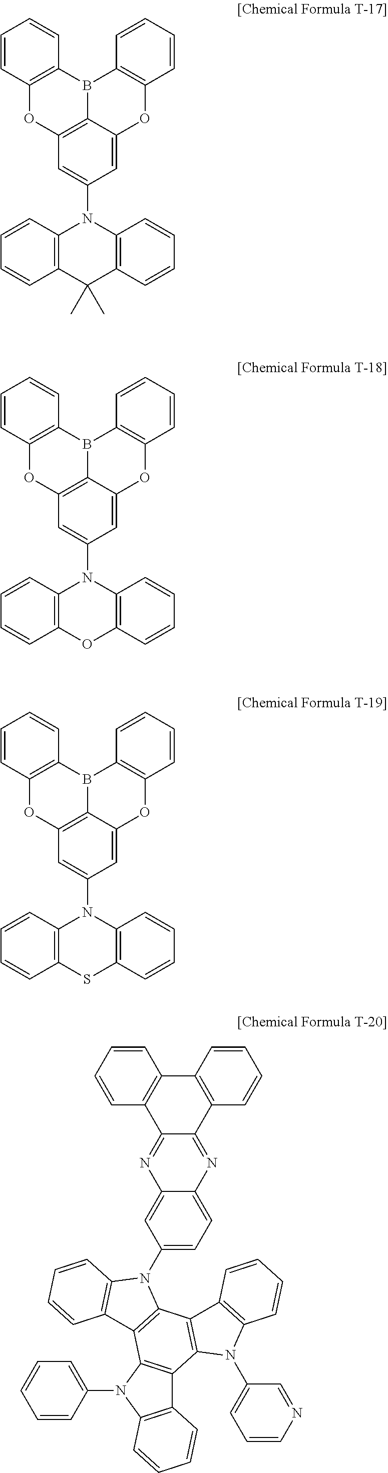 [SMILES: CC1(C)c2ccccc2N(c2cc3c4c(c2)Oc2ccccc2B4c2ccccc2O3)c2ccccc21 ; c1ccc2c(c1)Oc1cc(N3c4ccccc4Oc4ccccc43)cc3c1B2c1ccccc1O3 ; c1ccc2c(c1)Oc1cc(N3c4ccccc4Sc4ccccc43)cc3c1B2c1ccccc1O3 ; c1ccc(-n2c3ccccc3c3c2c2c4ccccc4n(-c4ccc5nc6c7ccccc7c7ccccc7c6nc5c4)c2c2c4ccccc4n(-c4cccnc4)c32)cc1]

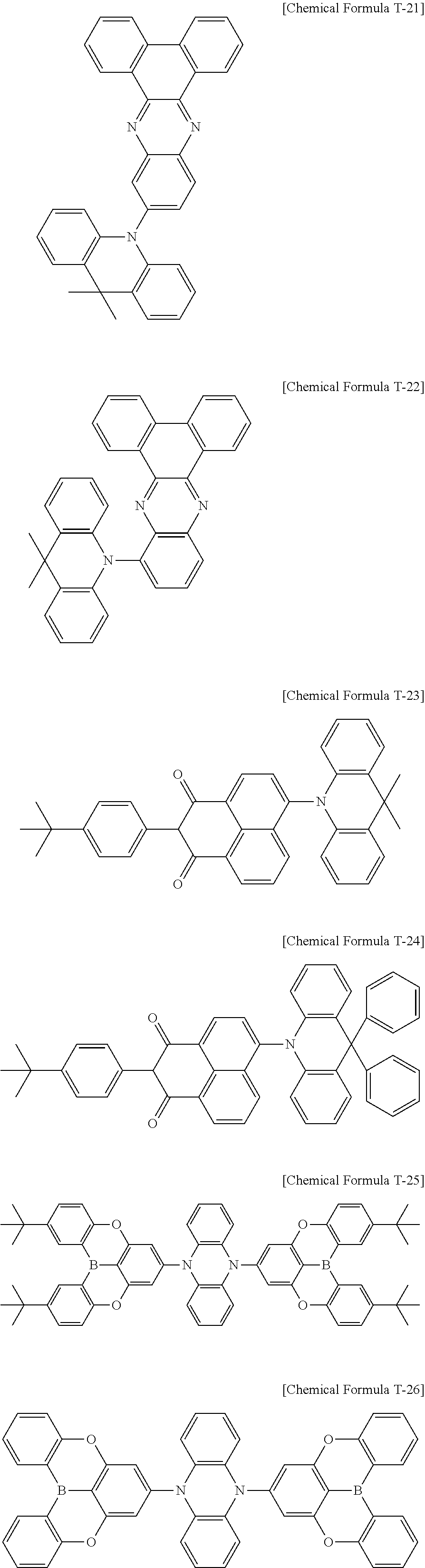

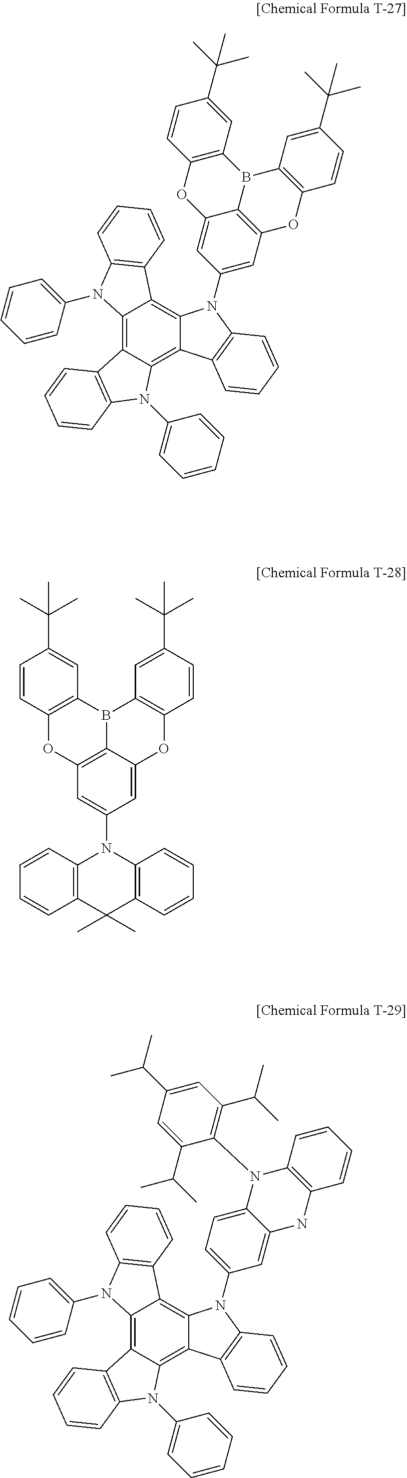 [SMILES: CC(C)(C)c1ccc2c(c1)B1c3cc(C(C)(C)C)ccc3Oc3cc(-n4c5ccccc5c5c6c(c7ccccc7n6-c6ccccc6)c6c(c7ccccc7n6-c6ccccc6)c54)cc(c31)O2 ; CC(C)(C)c1ccc2c(c1)B1c3cc(C(C)(C)C)ccc3Oc3cc(N4c5ccccc5C(C)(C)c5ccccc54)cc(c31)O2 ; CC(C)c1cc(C(C)C)c(N2c3ccccc3Nc3cc(-n4c5ccccc5c5c6c(c7ccccc7n6-c6ccccc6)c6c(c7ccccc7n6-c6ccccc6)c54)ccc32)c(C(C)C)c1]

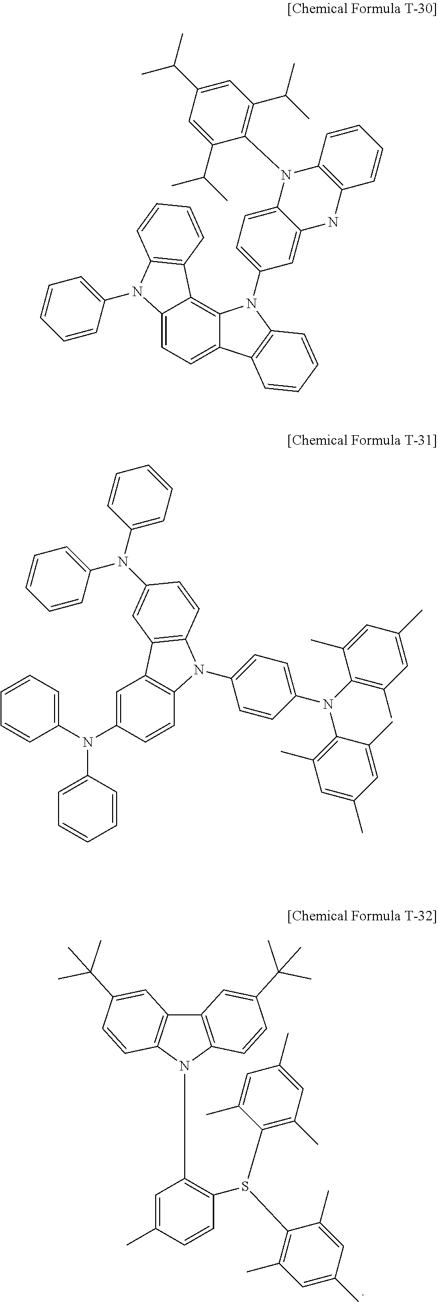

7. The method of claim 1, wherein the organic phosphor is a phosphor having a luminescence efficiency of 80% or more and having a boron compound as a main structure.

8. The method of claim 7, wherein the phosphor having the boron compound as the main structure is a compound represented by Chemical Formula 2 below: 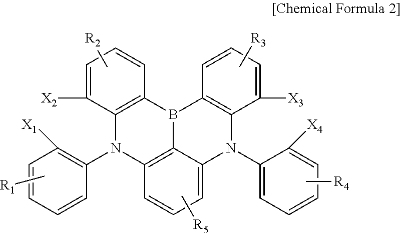
in Chemical Formula 2,
R₁ to R₅ each independently correspond to any one selected from the group consisting of hydrogen, deuterium, a halogen group, a hydroxyl group, a cyano group, a nitro group, an amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, and
X₁ to X₄ are each independently hydrogen, or are bonded to each other to form a ring.

9. The method of claim 7, wherein the boron compound is any one of compounds represented by the following Chemical Formulas D-1 to D-30:

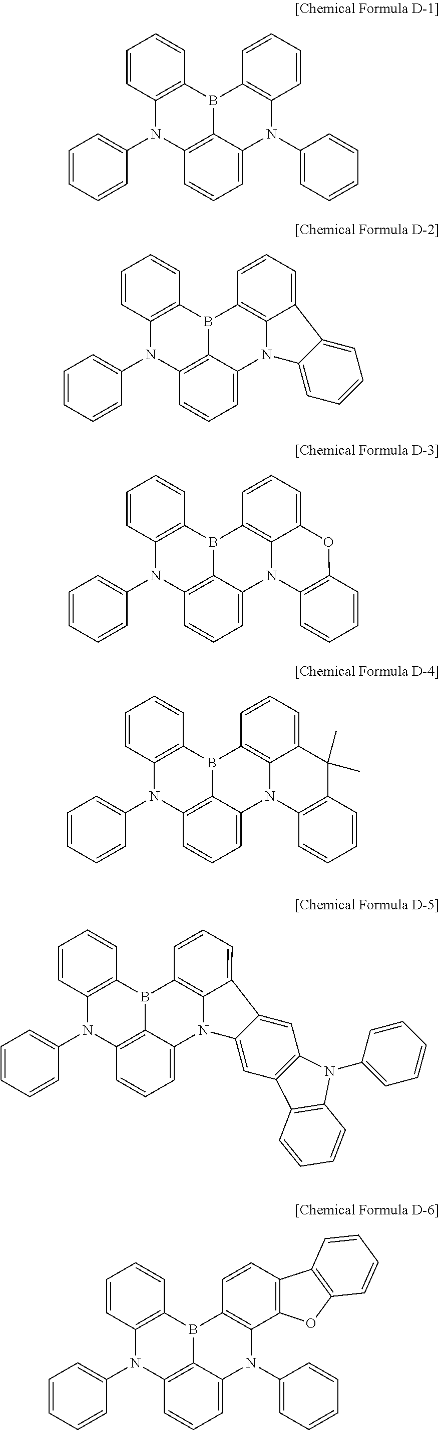 [SMILES: c1ccc(N2c3ccccc3B3c4ccccc4N(c4ccccc4)c4cccc2c43)cc1 ; c1ccc(N2c3ccccc3B3c4c2cccc4-n2c4ccccc4c4cccc3c42)cc1 ; c1ccc(N2c3ccccc3B3c4cccc5c4N(c4ccccc4O5)c4cccc2c43)cc1 ; CC1(C)c2ccccc2N2c3cccc4c3B(c3ccccc3N4c3ccccc3)c3cccc1c32 ; c1ccc(N2c3ccccc3B3c4c2cccc4-n2c4cc5c6ccccc6n(-c6ccccc6)c5cc4c4cccc3c42)cc1 ; c1ccc(N2c3ccccc3B3c4ccc5c(oc6ccccc65)c4N(c4ccccc4)c4cccc2c43)cc1]

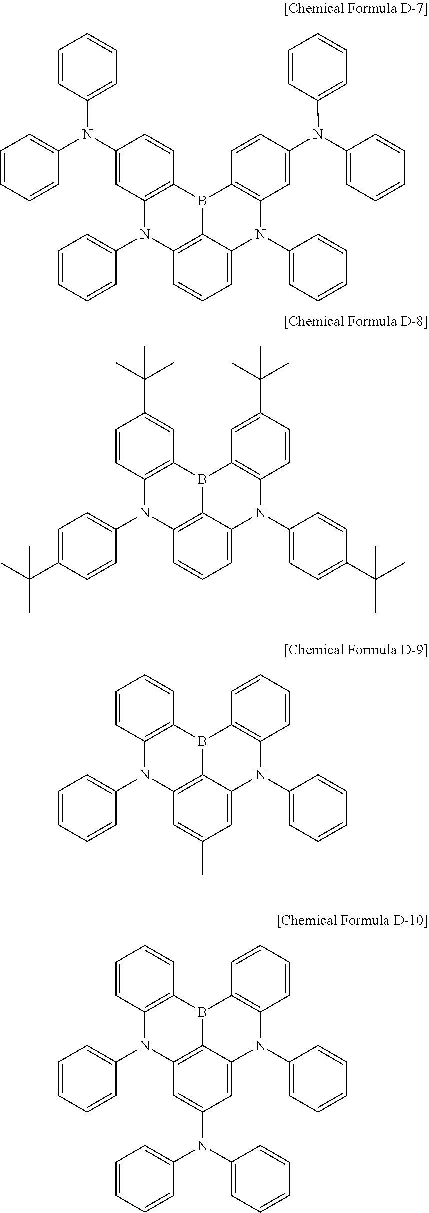 [SMILES: c1ccc(N(c2ccccc2)c2ccc3c(c2)N(c2ccccc2)c2cccc4c2B3c2ccc(N(c3ccccc3)c3ccccc3)cc2N4c2ccccc2)cc1 ; CC(C)(C)c1ccc(N2c3ccc(C(C)(C)C)cc3B3c4cc(C(C)(C)C)ccc4N(c4ccc(C(C)(C)C)cc4)c4cccc2c43)cc1 ; Cc1cc2c3c(c1)N(c1ccccc1)c1ccccc1B3c1ccccc1N2c1ccccc1 ; c1ccc(N(c2ccccc2)c2cc3c4c(c2)N(c2ccccc2)c2ccccc2B4c2ccccc2N3c2ccccc2)cc1]

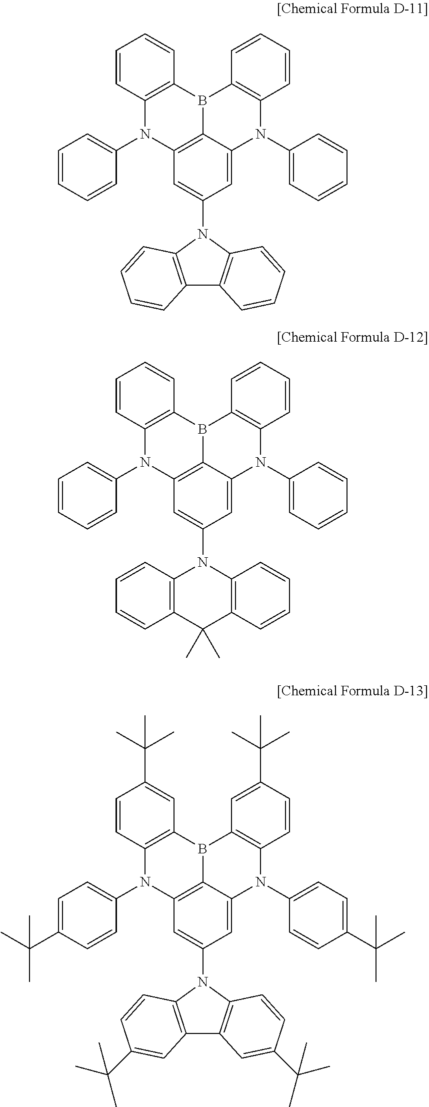 [SMILES: c1ccc(N2c3ccccc3B3c4ccccc4N(c4ccccc4)c4cc(-n5c6ccccc6c6ccccc65)cc2c43)cc1 ; CC1(C)c2ccccc2N(c2cc3c4c(c2)N(c2ccccc2)c2ccccc2B4c2ccccc2N3c2ccccc2)c2ccccc21 ; CC(C)(C)c1ccc(N2c3ccc(C(C)(C)C)cc3B3c4cc(C(C)(C)C)ccc4N(c4ccc(C(C)(C)C)cc4)c4cc(-n5c6ccc(C(C)(C)C)cc6c6cc(C(C)(C)C)ccc65)cc2c43)cc1]

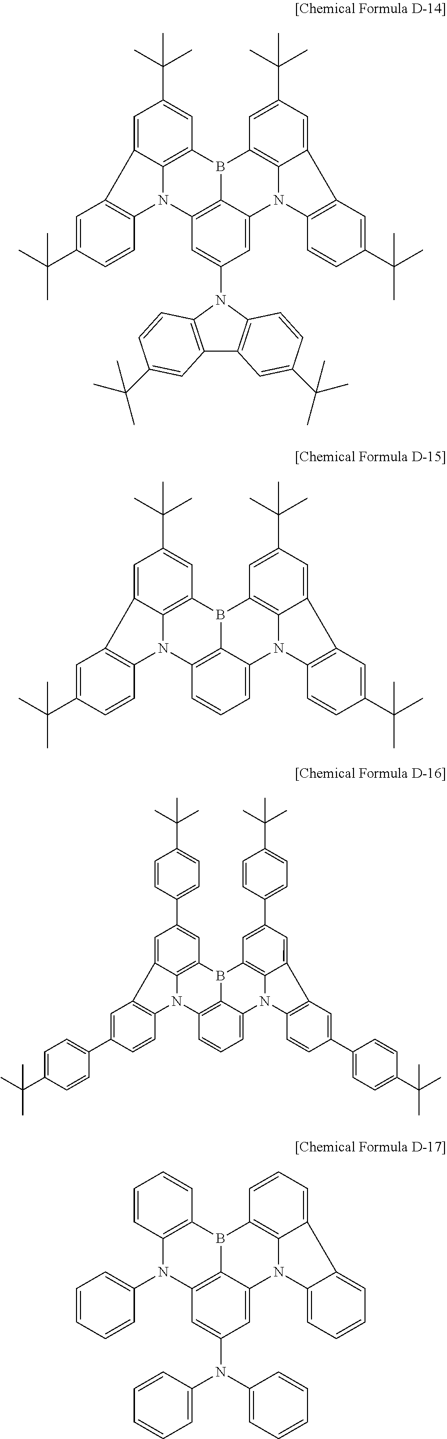

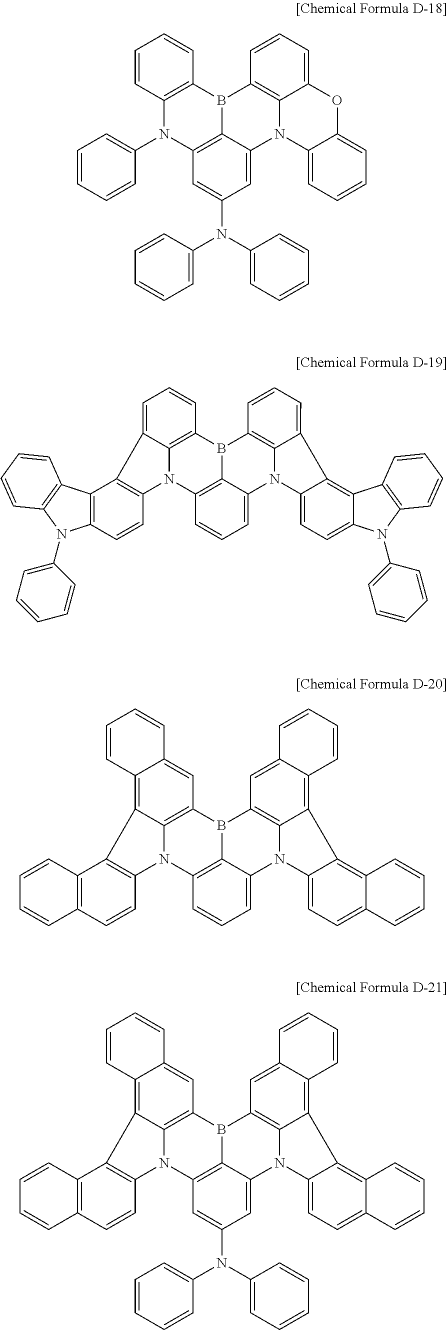 [SMILES: c1ccc(N(c2ccccc2)c2cc3c4c(c2)N2c5ccccc5Oc5cccc(c52)B4c2ccccc2N3c2ccccc2)cc1 ; c1ccc(-n2c3ccccc3c3c4c5cccc6c5n(c4ccc32)-c2cccc3c2B6c2cccc4c5c6c7ccccc7n(-c7ccccc7)c6ccc5n-3c24)cc1 ; c1cc2c3c(c1)-n1c4ccc5ccccc5c4c4c5ccccc5cc(c41)B3c1cc3ccccc3c3c4c5ccccc5ccc4n-2c13 ; c1ccc(N(c2ccccc2)c2cc3c4c(c2)-n2c5ccc6ccccc6c5c5c6ccccc6cc(c52)B4c2cc4ccccc4c4c5c6ccccc6ccc5n-3c24)cc1]

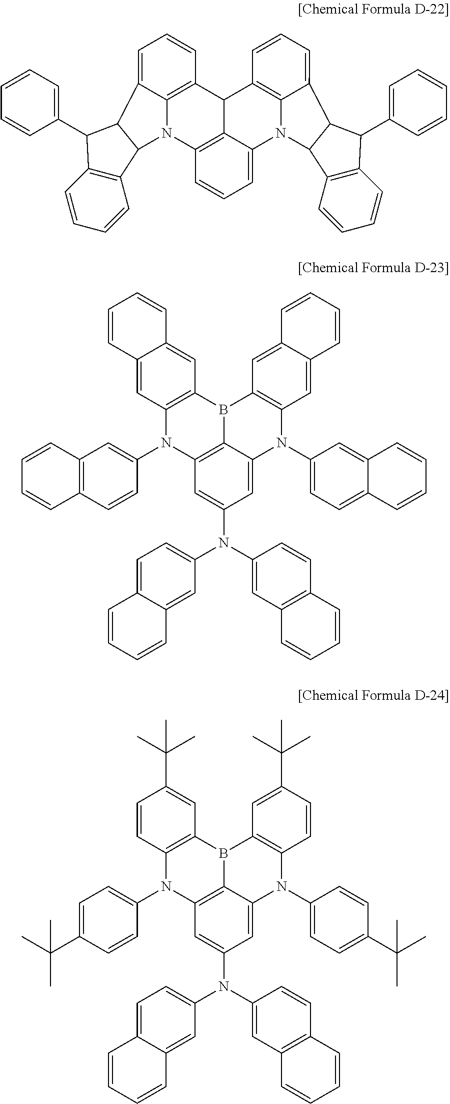 [SMILES: c1ccc(C2c3ccccc3C3C2c2cccc4c2N3c2cccc3c2C4c2cccc4c2N3C2c3ccccc3C(c3ccccc3)C42)cc1 ; c1ccc2cc(N(c3cc4c5c(c3)N(c3ccc6ccccc6c3)c3cc6ccccc6cc3B5c3cc5ccccc5cc3N4c3ccc4ccccc4c3)c3ccc4ccccc4c3)ccc2c1 ; CC(C)(C)c1ccc(N2c3ccc(C(C)(C)C)cc3B3c4cc(C(C)(C)C)ccc4N(c4ccc(C(C)(C)C)cc4)c4cc(N(c5ccc6ccccc6c5)c5ccc6ccccc6c5)cc2c43)cc1]

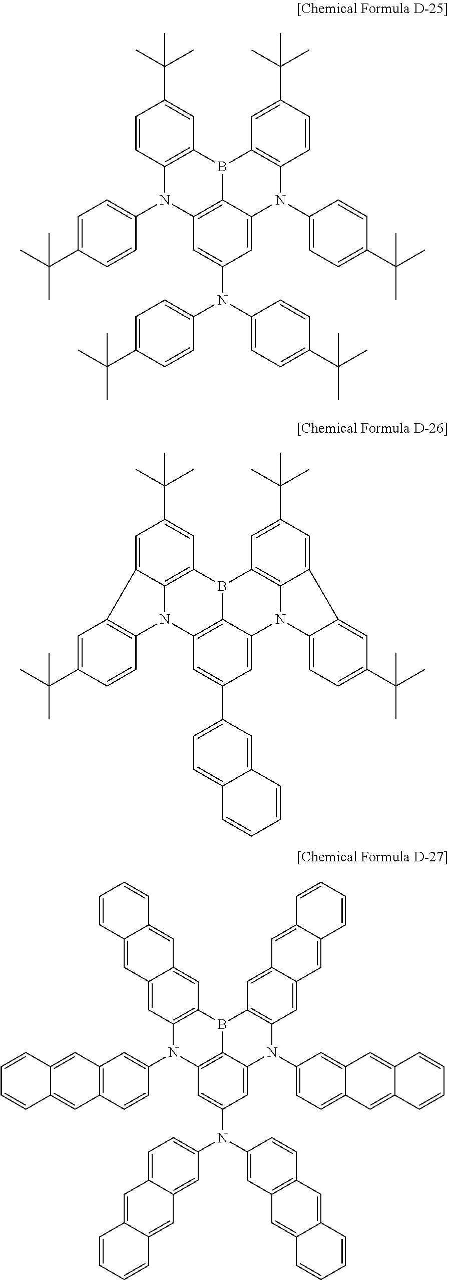

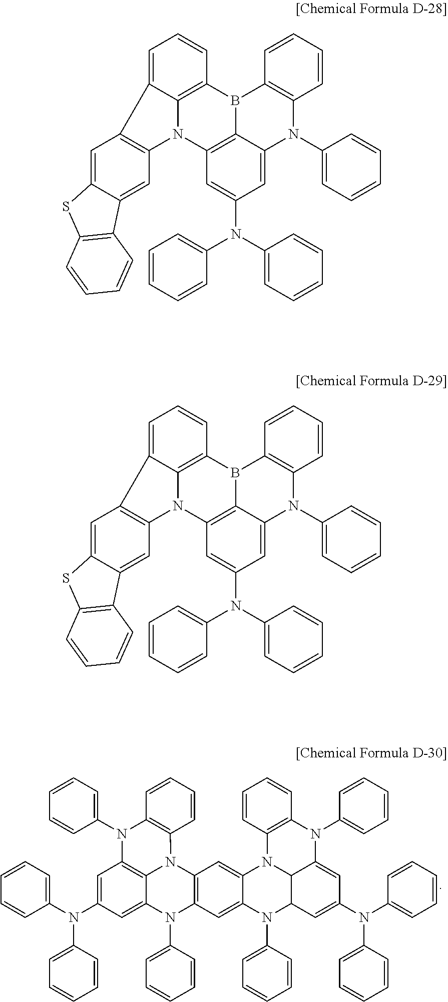 [SMILES: c1ccc(N(c2ccccc2)c2cc3c4c(c2)-n2c5cc6c(cc5c5cccc(c52)B4c2ccccc2N3c2ccccc2)sc2ccccc26)cc1 ; c1ccc(N(c2ccccc2)c2cc3c4c(c2)-n2c5cc6c(cc5c5cccc(c52)B4c2ccccc2N3c2ccccc2)sc2ccccc26)cc1 ; C1=C(N(c2ccccc2)c2ccccc2)C=C2C3C1N(c1ccccc1)c1cc4c(cc1N3c1ccccc1N2c1ccccc1)N1c2ccccc2N(c2ccccc2)c2cc(N(c3ccccc3)c3ccccc3)cc(c21)N4c1ccccc1]

10. The method of claim 7, wherein the phosphor having the boron compound as the main structure is a compound represented by Chemical Formula 3 below: 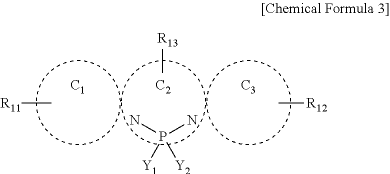
in Chemical Formula 3,
C₁ to C₃ each have a 5-membered or 6-membered ring structure,
R₁₁ and R₁₂ are each independently substituted with 1, 2 or 3 substituents, and each of the substituents independently corresponds to any one selected from the group consisting of hydrogen, deuterium, a halogen group, a hydroxyl group, a cyano group, a nitro group, an amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted thioether group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, or two or more substituents are bonded to each other to form a ring,
R₁₃ corresponds to any one selected from the group consisting of hydrogen, deuterium, a halogen group, a hydroxyl group, a cyano group, a nitro group, an amino group, an amidino group, a hydrazino group, a hydrazono group, a substituted or unsubstituted alkyl group, a substituted or unsubstituted an alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted thioether group, a substituted or unsubstituted a heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, and
Y₁ and Y₂ are each independently a fluorine group or an alkoxy group.

11. The method of claim 10, wherein the boron compound is any one of compounds represented by the following Chemical Formulas B-1 to B-32.

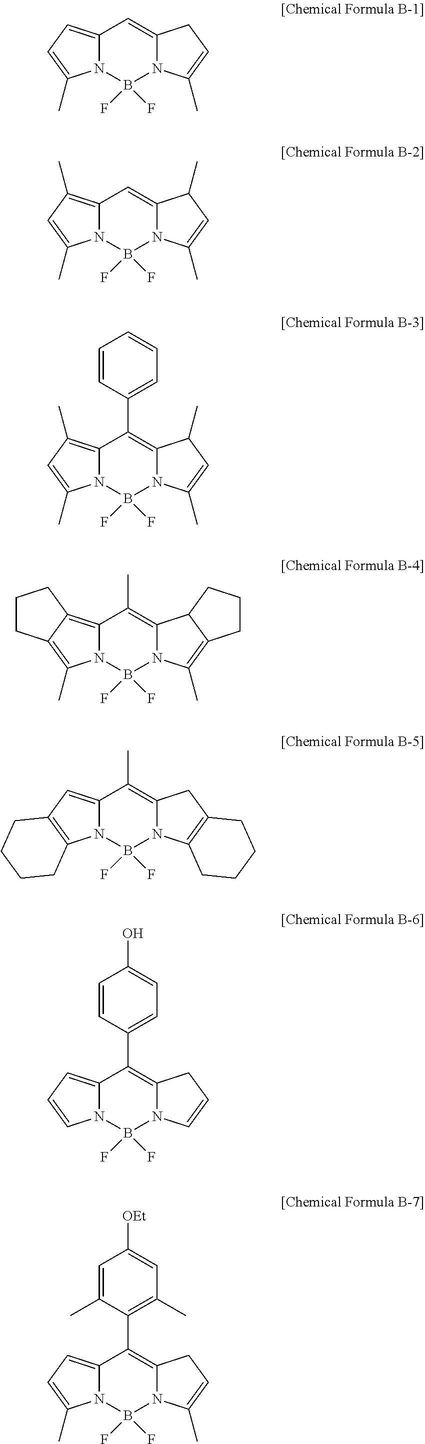

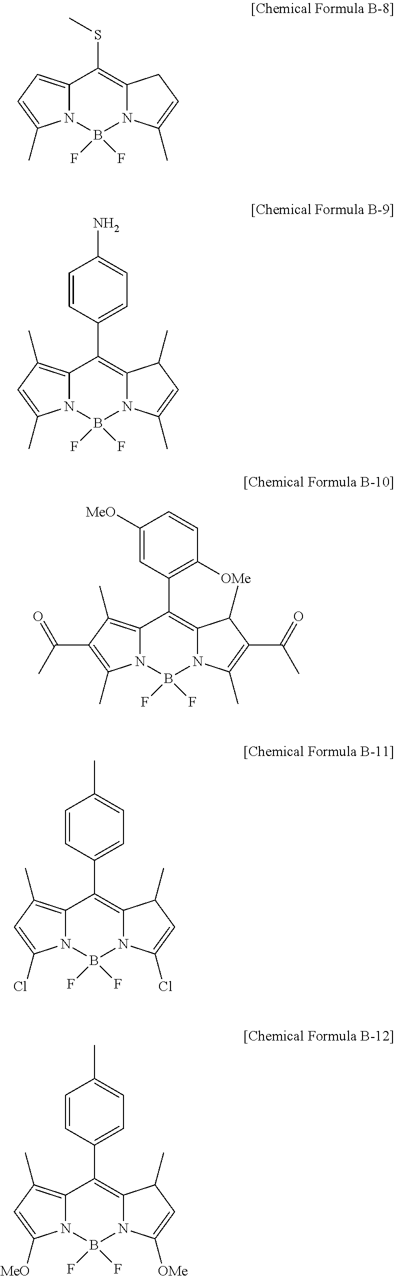

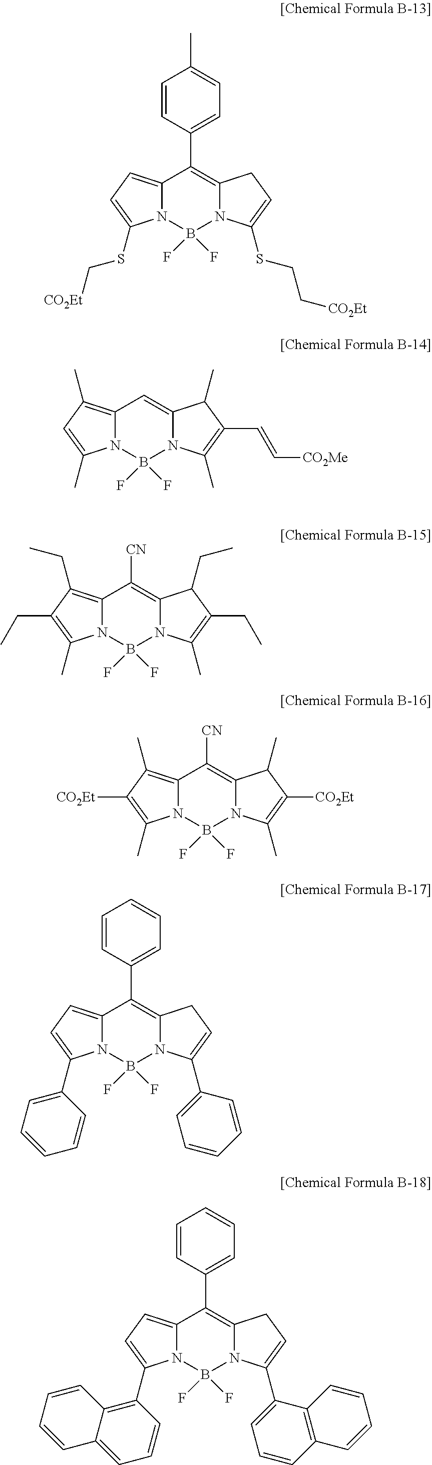

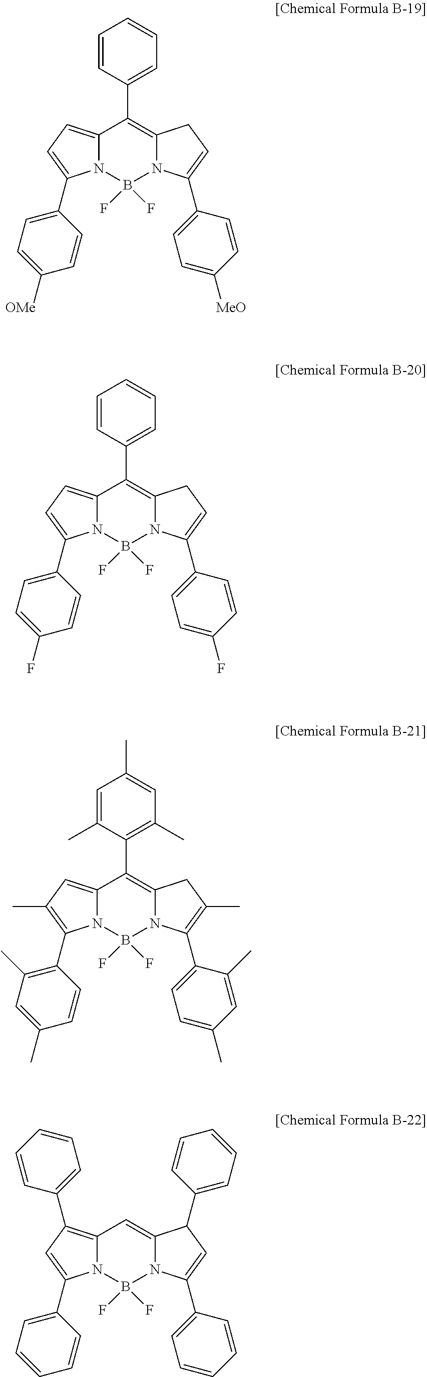

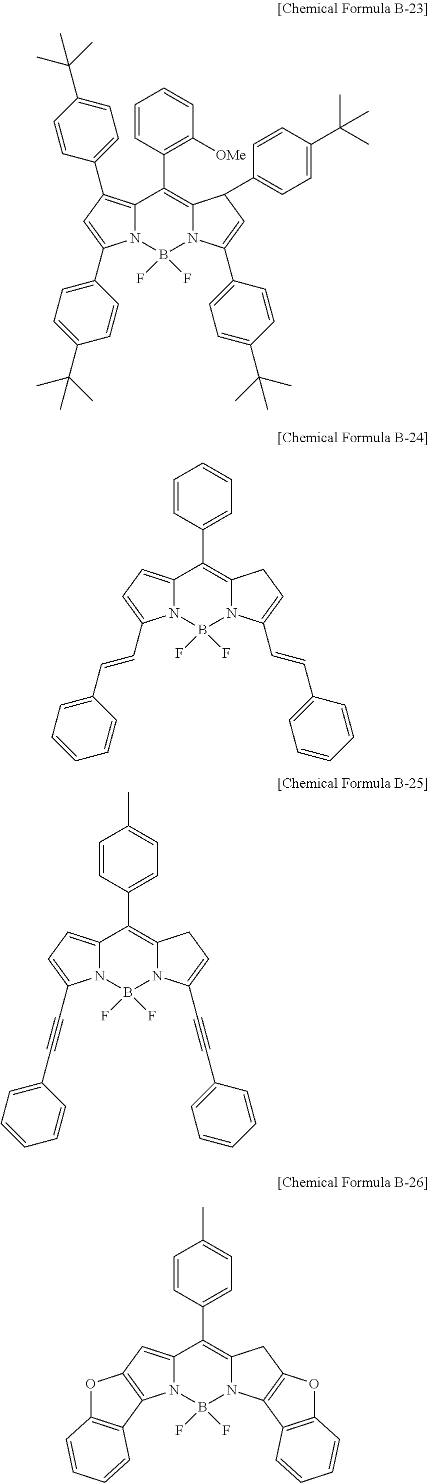

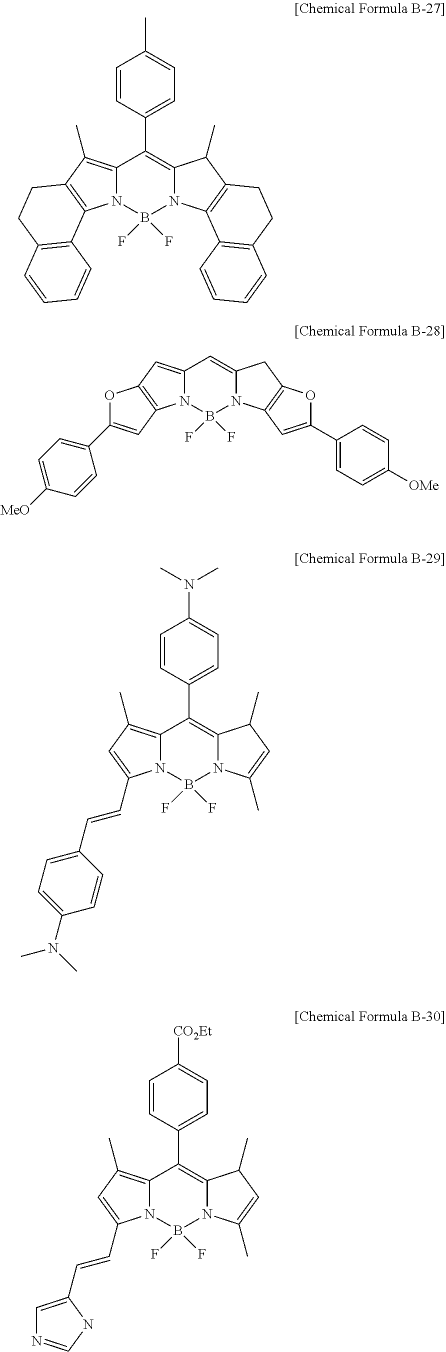

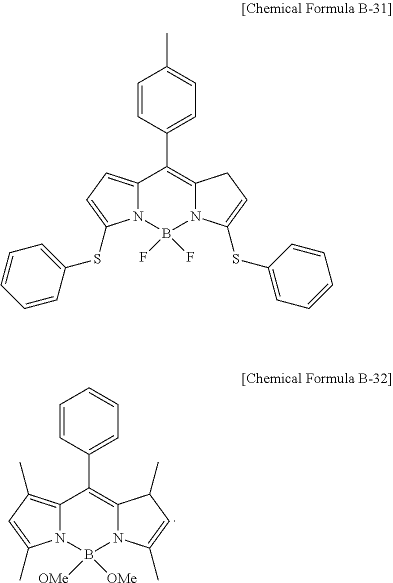

12. The method of claim 1, wherein the first solvent is any one selected from the group consisting of an aqueous solvent, an alcohol-based solvent, a ketone-based solvent, an ether-based solvent, a sulfoxide-based solvent, an ester-based solvent, and mixtures thereof.

13. The method of claim 1, wherein the surfactant is any one selected from the group consisting of an anionic surfactant, a cationic surfactant, a zwitterionic surfactant, a nonionic surfactant, and mixtures thereof.

14. The method of claim 1, wherein the number of moles of the surfactant is 20 to 1000 times based on the number of moles of the organic phosphor.

15. Light-emission type organic nanoparticles prepared by the method of preparing light-emission type organic nanoparticles of claim 1.

16. A composition for a color conversion film, comprising:
a polymer resin; and
2 to 20 parts by weight of the light-emission type organic nanoparticles of claim 15, based on 100 parts by weight of the polymer resin.

17. A color conversion film coated with the composition for a color conversion film of claim 16 on a substrate.

18. A display device comprising the color conversion film of claim 17.

19. A light emitting diode device comprising the color conversion film of claim 17.
